(19) United States
(12) Patent Application Publication
(10) Pub. No.: US 2026/0271709 A1
(43) Pub. Date: Sep. 10, 2026

(54) SEMICONDUCTOR DEVICE, METHOD FOR MANUFACTURING SEMICONDUCTOR DEVICE, AND VEHICLE

(71) Applicant: ROHM CO., LTD., Kyoto-shi (JP)

(72) Inventors: Masashi HAYASHIGUCHI, Kyoto-shi (JP); Yoshihisa TSUKAMOTO, Kyoto-shi (JP); Hidetoshi ABE, Kyoto-shi (JP); Hideki SAWADA, Kyoto-shi (JP)

(21) Appl. No.: 19/665,227

(22) Filed: May 1, 2026

Related U.S. Application Data
(63) Continuation of application No. PCT/JP2024/039059, filed on Nov. 1, 2024.

(30) Foreign Application Priority Data
Nov. 9, 2023 (JP) 2023-191442

(51) Int. Cl. H10W 40/22; B60R 16/023; H10D 80/20; H10W 40/00; H10W 40/47; H10W 90/00

(52) U.S. Cl. CPC H10W 40/228; H10D 80/251; H10W 40/03; H10W 40/47; H10W 90/736; B60R 16/0231

(57) ABSTRACT

The semiconductor device comprises a first semiconductor element having a first electrode, a first terminal opposed the first electrode, a first heat dissipation member electrically connected to the first terminal and conductively connected to the first electrode, and a first protective layer covering a portion of the first semiconductor element. The first feat dissipation member is conductively connected to the first electrode. The first protective layer is an insulator. A first flow path is provided between the first semiconductor element and the first terminal. The first heat dissipation member is housed within the first flow path. A first opening to expose the first electrode is provided in the first protective layer. The first heat dissipation member has a first end portion inserted into the first opening. A gap is provided between the first end portion and the first protective layer at the first opening.

### TECHNICAL FIELD

The present disclosure relates to a semiconductor device and a method for manufacturing the same, and a vehicle equipped with the semiconductor device.

### BACKGROUND ART

WO 2017/094370 discloses an example of a semiconductor module including a semiconductor device and a cooler. The cooler includes a housing having a hollow space and a heat sink. The housing has an opening communicating with the hollow space. The heat sink is mounted on the housing such that it blocks the opening. A portion of the heat sink is housed within the hollow space. The semiconductor device is bonded to the portion of the heat sink that protrudes from the hollow space to the outside. When a coolant (such as cooling water) is circulated through the hollow space, the coolant contacts the heat sink. This enables efficient cooling of the semiconductor device via the heat sink.

However, in the configuration of the semiconductor module disclosed in WO 2017/094370, the cooling effect on the semiconductor device is not sufficiently achieved relative to the scale of the cooler.

### BRIEF DESCRIPTION OF THE DRAWINGS

FIG. 1 is a plan view of a semiconductor device according to a first embodiment of the present disclosure.

FIG. 2 is a plan view corresponding to FIG. 1, showing the housing in transparent form.

FIG. 3 is a plan view corresponding to FIG. 2, omitting the depiction of a third terminal and a plurality of fourth heat dissipation members.

FIG. 4 is a plan view corresponding to FIG. 3, omitting the depiction of a third signal terminal, a fourth signal terminal, a plurality of second semiconductor elements, a plurality of second protective layers, a plurality of third heat dissipation members, a plurality of second gate pillars, a plurality of second detection pillars, a plurality of third leads, and a plurality of fourth leads.

FIG. 5 is a plan view corresponding to FIG. 4, omitting the depiction of a first terminal.

FIG. 6 is a bottom view of the semiconductor device shown in FIG. 1.

FIG. 7 is a cross-sectional view along line VII-VII in FIG. 3.

FIG. 8 is a cross-sectional view along line VIII-VIII in FIG. 3.

FIG. 9 is a cross-sectional view along line IX-IX in FIG. 3.

FIG. 10 is a partially enlarged view of FIG. 7.

FIG. 11 is a partially enlarged view of FIG. 8, showing one of a plurality of first semiconductor elements and its vicinity.

FIG. 12 is a partial enlarged view of FIG. 8, showing one of a plurality of second semiconductor elements and its vicinity.

FIG. 13 is a cross-sectional view showing a state where the refrigerant flows downward in the semiconductor device shown in FIG. 1.

FIG. 14 is a partially enlarged cross-sectional view of a semiconductor device according to a variation of the first embodiment of the present disclosure.

FIG. 15 is a cross-sectional view illustrating a first process in the manufacturing method of the semiconductor device shown in FIG. 1.

FIG. 16 is a cross-sectional view illustrating a second process in the manufacturing method of the semiconductor device shown in FIG. 1.

FIG. 17 is a cross-sectional view illustrating a third process in the manufacturing method of the semiconductor device shown in FIG. 1.

FIG. 18 is a cross-sectional view illustrating a fourth process in the manufacturing method of the semiconductor device shown in FIG. 1.

FIG. 19 is a schematic diagram of a vehicle equipped with the semiconductor device shown in FIG. 1.

FIG. 20 is a plan view of a semiconductor device according to a second embodiment of the present disclosure, corresponding to FIG. 3.

FIG. 21 is a plan view of the semiconductor device shown in FIG. 20, corresponding to FIG. 5.

FIG. 22 is a cross-sectional view along line XXII-XXII in FIG. 20.

FIG. 23 is a plan view of a semiconductor device according to a third embodiment of the present disclosure, corresponding to FIG. 3.

FIG. 24 is a plan view of the semiconductor device shown in FIG. 23, corresponding to FIG. 5.

FIG. 25 is a cross-sectional view along line XXV-XXV in FIG. 23.

FIG. 26 is a plan view of a semiconductor device according to a fourth embodiment of the present disclosure.

FIG. 27 is a bottom view of the semiconductor device shown in FIG. 26.

FIG. 28 is a cross-sectional view along line XXVIII-XXVIII in FIG. 26.

FIG. 29 is a cross-sectional view along line XXIX-XXIX in FIG. 26.

FIG. 30 is a plan view of a semiconductor device according to a fifth embodiment of the present disclosure.

FIG. 31 is a plan view of the semiconductor device shown in FIG. 30, corresponding to FIG. 2.

FIG. 32 is a plan view of the semiconductor device shown in FIG. 30, corresponding to FIG. 3.

FIG. 33 is a plan view of the semiconductor device shown in FIG. 30, corresponding to FIG. 5.

FIG. 34 is a cross-sectional view along line XXXIV-XXXIV in FIG. 31.

FIG. 35 is a cross-sectional view along line XXXV-XXXV in FIG. 31.

### DETAILED DESCRIPTION OF EMBODIMENTS

The details of the present disclosure will be described with reference to the accompanying drawings.

### First Embodiment

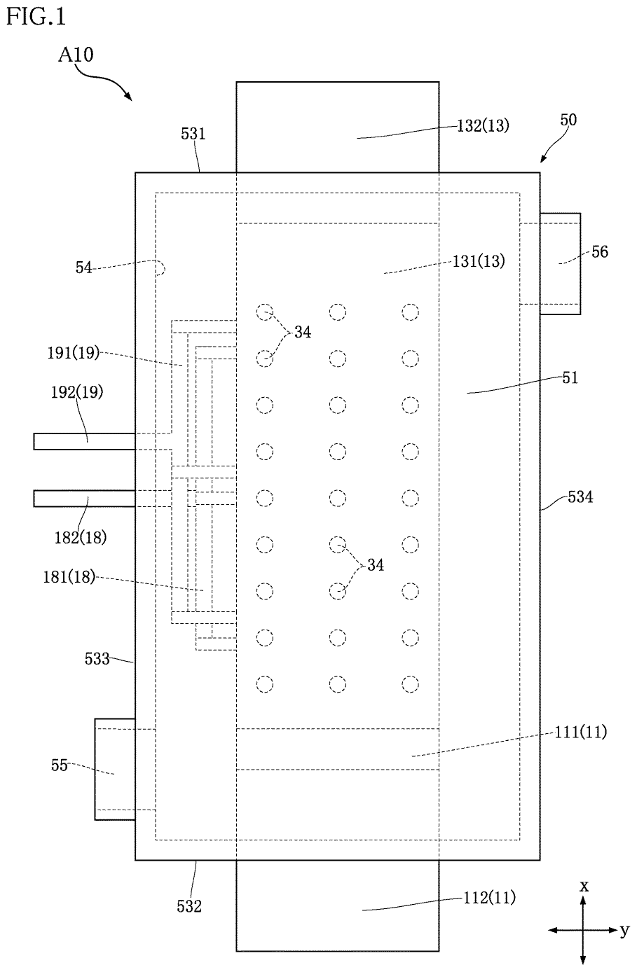

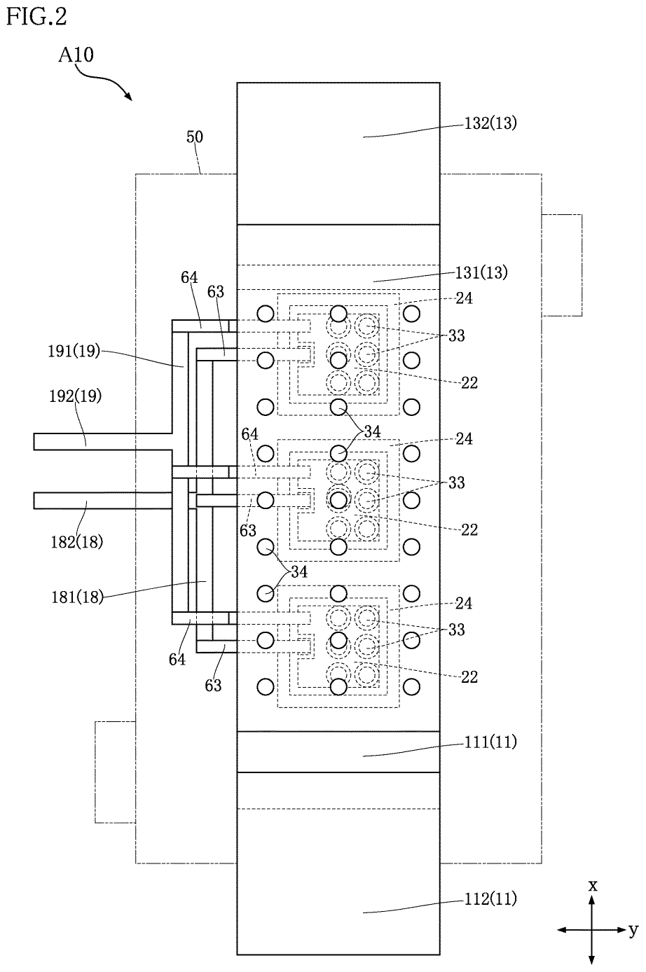

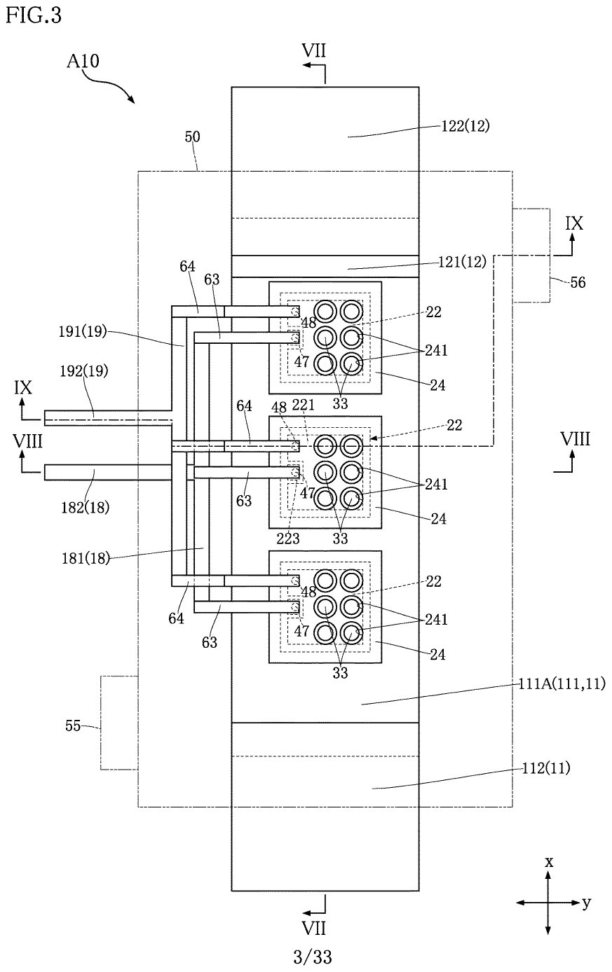

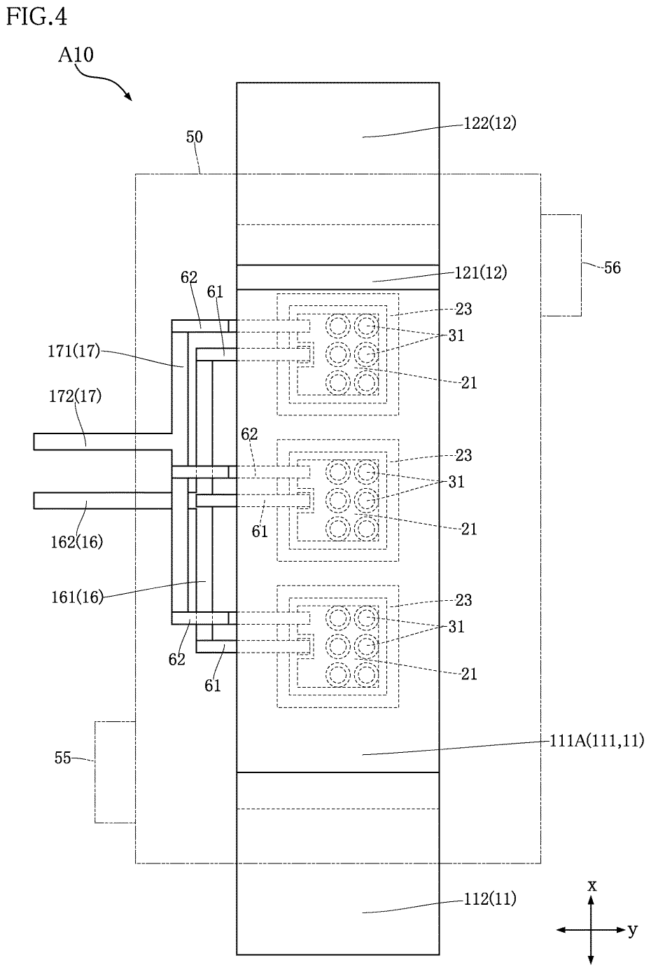

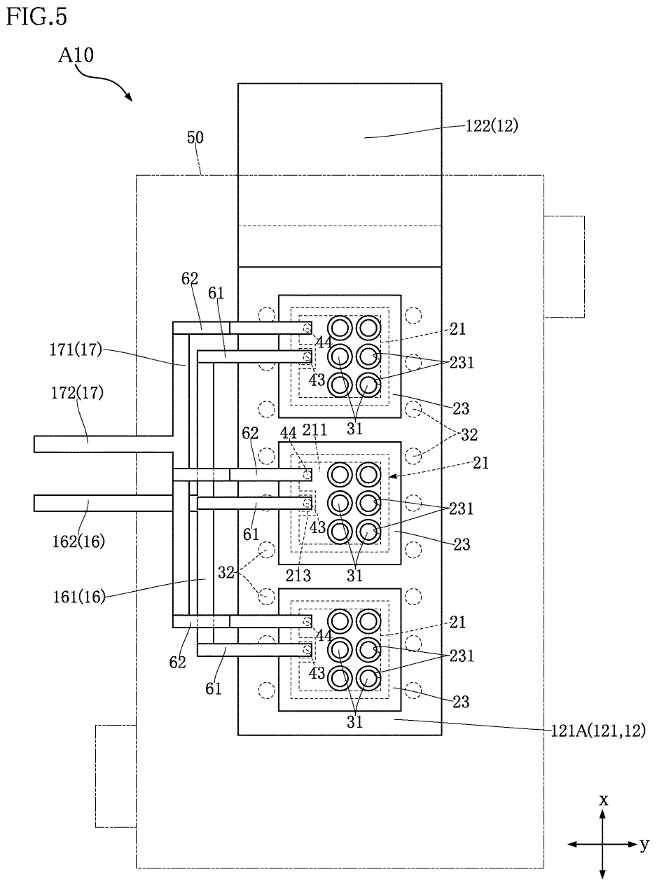

Based on FIGS. 1 to 13, a semiconductor device A10 according to a first embodiment of the present disclosure is described. Generally, the semiconductor device A10 is used in power conversion circuits such as inverters. The semiconductor device A10 includes a first terminal 11, a second terminal 12, a third terminal 13, a plurality of first semiconductor elements 21, a plurality of second semiconductor elements 22, a plurality of first protective layers 23, a plurality of second protective layers 24, a plurality of first heat dissipation members 31, a plurality of second heat dissipation members 32, a plurality of third heat dissipation members 33, a plurality of fourth heat dissipation members 34, and a housing 50. The semiconductor device A10 includes a first bonding layer 25, a second bonding layer 26, a third bonding layer 27, a fourth bonding layer 28, a fifth bonding layer 29, a plurality of first gate pillars 43, a plurality of first detection pillars 44, a plurality of second gate pillars 47, and a plurality of second detection pillars 48. Furthermore, the semiconductor device A10 includes a first signal terminal 16, a second signal terminal 17, a third signal terminal 18, a fourth signal terminal 19, a plurality of first leads 61, a plurality of second leads 62, a plurality of third leads 63, and a plurality of fourth leads 64. Here, FIGS. 2 to 5 show the housing 50 as being transparent for ease of understanding. In FIGS. 2 to 5, the transparent housing 50 is indicated by imaginary lines (two-dot dashed lines). In FIG. 3, for ease of understanding, the depiction of the third terminal 13 and the plurality of fourth heat dissipation members 34 is omitted in FIG. 2. In FIG. 4, unlike FIG. 3, for ease of understanding, the third signal terminal 18, the fourth signal terminal 19, the plurality of second semiconductor elements 22, the plurality of second protective layers 24, the plurality of third heat dissipation members 33, the plurality of second gate pillars 47, the plurality of second detection pillars 48, the plurality of third leads 63, and the plurality of fourth leads 64 are omitted. In FIG. 5, unlike FIG. 4, for ease of understanding, the first terminal 11 is omitted.

In describing the semiconductor device A10, for convenience, the normal direction of a first mounting surface 121A of the second terminal 12 described later is referred to as a “first direction z”. The direction orthogonal to the first direction z is referred to as a “second direction x”. The direction orthogonal to both the first direction z and the second direction x is referred to as a “third direction y”.

In the semiconductor device A10, a half-bridge circuit is formed including the plurality of first semiconductor elements 21 and the plurality of second semiconductor elements 22. The semiconductor device A10 converts a DC power supplied to the second terminal 12 and the third terminal 13 into an AC power using the plurality of first semiconductor elements 21 and the plurality of second semiconductor elements 22. The second terminal 12 is the P terminal (positive terminal). The third terminal 13 is the N terminal (negative terminal). The converted AC power is input from the first terminal 11 to a power supply target such as a motor.

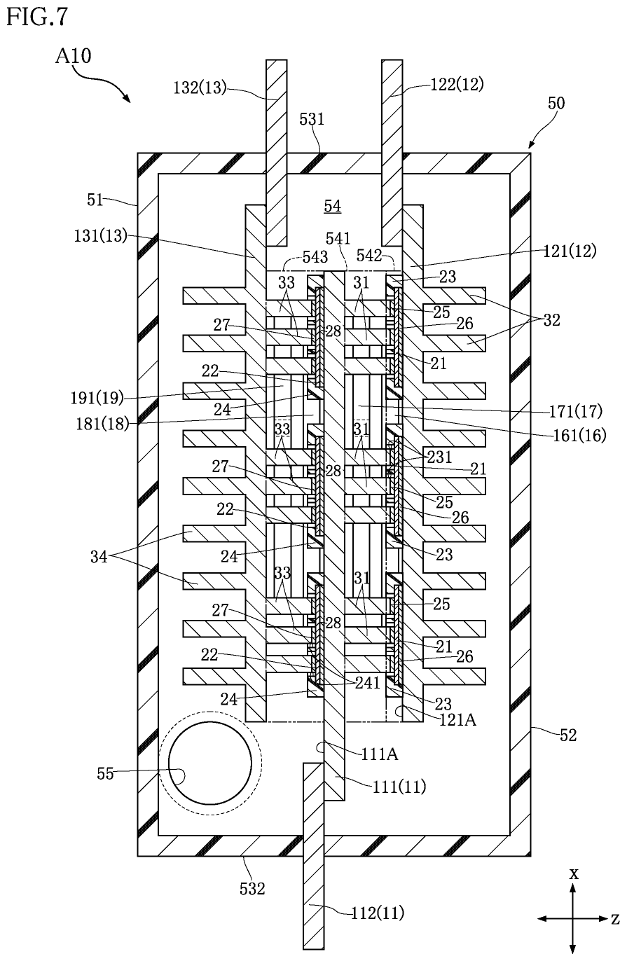

As shown in FIGS. 7 to 9, the housing 50 supports the first terminal 11, the second terminal 12, the third terminal 13, the first signal terminal 16, the second signal terminal 17, the third signal terminal 18, and the fourth signal terminal 19, respectively. The housing 50 is made of an insulator containing resin. Alternatively, the housing 50 may be made of a conductor containing a metal such as aluminum (Al).

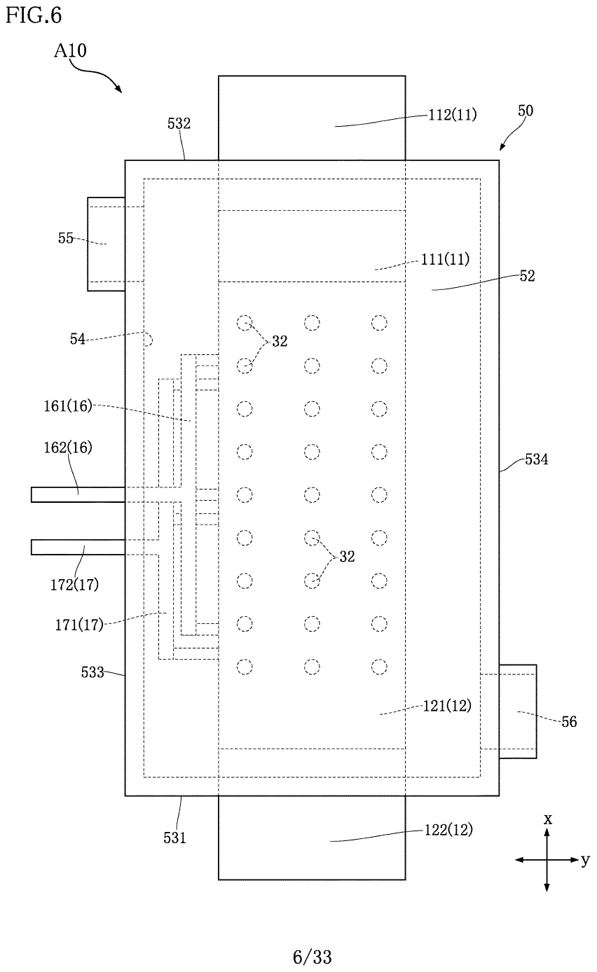

As shown in FIGS. 1 and 6, the housing 50 has a top surface 51, a bottom surface 52, a first side surface 531, a second side surface 532, a third side surface 533, and a fourth side surface 534. The top surface 51 faces one side in the first direction z. The bottom surface 52 faces away from the top surface 51 in the first direction z. The first side surface 531 and the second side surface 532 face away from each other in the second direction x. The third side surface 533 and the fourth side surface 534 face away from each other in the third direction y.

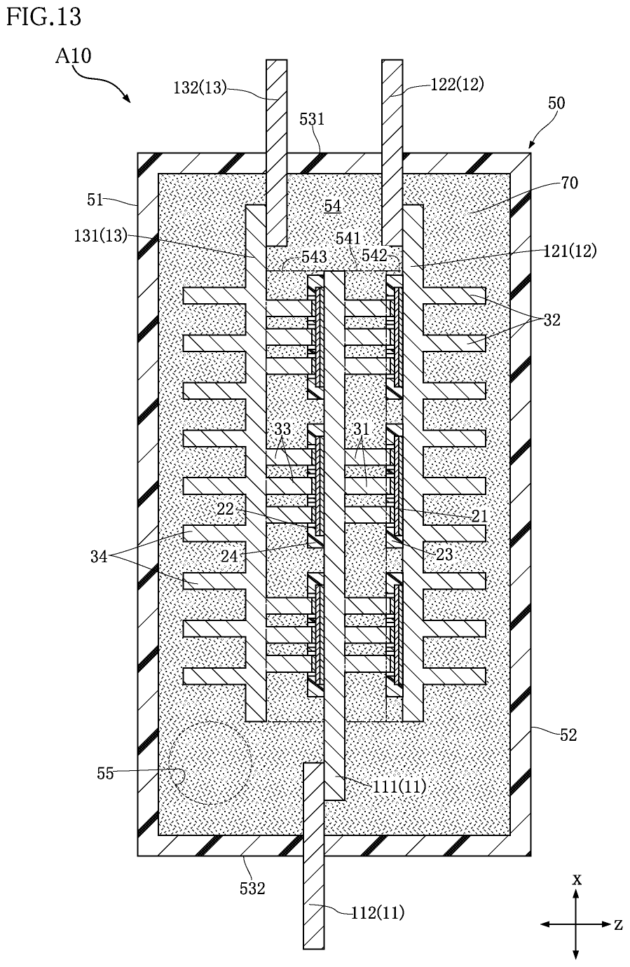

As shown in FIGS. 7 to 9, the housing 50 includes a hollow portion 54. Air flows into the hollow portion 54. Alternatively, as shown in FIG. 13, the hollow portion 54 may be configured to be constantly filled with refrigerant 70. The hollow portion 54 includes a first flow path 541, a second flow path 542, and a third flow path 543. The first flow path 541 is provided between the plurality of first semiconductor elements 21 and the first terminal 11 in the first direction z. The second flow path 542 is provided between the second terminal 12 and the first flow path 541 in the first direction z. The second flow path 542 connects to the first flow path 541. The third flow path 543 is provided between the first terminal 11 and the third terminal 13 in the first direction z. Here, the refrigerant 70 shown in FIG. 13 must be an insulator. In the present disclosure, if the refrigerant 70 is an insulator, the composition of the refrigerant 70 is not limited.

As shown in FIGS. 1, 3, 4, and 6, the housing 50 is provided with an inlet 55 and an outlet 56. The inlet 55 is opened on the third side surface 533 and communicates with the hollow portion 54. The outlet 56 is opened on the fourth side surface 534 and communicates with the hollow portion 54. Within the housing 50, the refrigerant 70 shown in FIG. 13 flows into the hollow portion 54 through the inlet 55. The refrigerant 70 flowing into the hollow portion 54 is discharged through the outlet 56. As shown in FIG. 4, the inlet 55 and the outlet 56 are positioned on sides opposite to each other in the second direction x, with respect to the plurality of first heat dissipation members 31.

As shown in FIGS. 7 to 9, the first terminal 11 is positioned on one side in the first direction z of the plurality of first semiconductor elements 21. The first terminal 11 is, for example, a metal plate containing copper (Cu). The first terminal 11 has a first base portion 111 and a first extension portion 112. The first base portion 111 is housed within the hollow portion 54 of the housing 50 and contacts the first flow path 541 and the third flow path 543. The first base portion 111 is strip-shaped extending in the second direction x. The first base portion 111 has a second mounting surface 111A facing the same side as the top surface 51 of the housing 50 in the first direction z. The first extension portion 112 is conductively bonded to one side in the second direction x of the first base portion 111. The first extension portion 112 is supported by the housing 50. A portion of the first extension portion 112 protrudes outward from the second side surface 532 of the housing 50.

As shown in FIGS. 7 to 9, the second terminal 12 is positioned on a side opposite in the first direction z to the first terminal 11 with respect to the plurality of first semiconductor elements 21. The second terminal 12 is, for example, a metal plate containing copper. The second terminal 12 has a second base portion 121 and a second extension portion 122. The second base portion 121 is housed within the hollow portion 54 of the housing 50 and contacts the second flow path 542. The second base portion 121 is strip-shaped extending in the second direction x. The second base portion 121 has a first mounting surface 121A facing the same side in the first direction z as the top surface 51 of the housing 50. The second extension portion 122 is conductively bonded to one side in the second direction x of the second base portion 121. The second extension portion 122 is supported by the housing 50. A portion of the second extension portion 122 protrudes outward from the first side surface 531 of the housing 50.

As shown in FIGS. 7 to 9, the third terminal 13 is positioned opposite in the first direction z from the first terminal 11 with respect to the plurality of second semiconductor elements 22. The third terminal 13 is, for example, a metal plate containing copper. The third terminal 13 has a third base portion 131 and a third extension portion 132. The third base portion 131 is housed within the hollow portion 54 of the housing 50 and contacts the third flow path 543. The third base portion 131 is strip-shaped extending in the second direction x. The third extension portion 132 is conductively bonded to one side in the second direction x of the third base portion 131. The third extension portion 132 is supported by the housing 50. A portion of the third extension portion 132 protrudes outward from the first side surface 531 of the housing 50.

As shown in FIGS. 7 to 9, the plurality of first semiconductor elements 21 are positioned between the first base portion 111 of the first terminal 11 and the second base portion 121 of the second terminal 12 in the first direction z. The plurality of first semiconductor elements 21 are housed in the second flow path 542 of the hollow portion 54 of the housing 50. The plurality of first semiconductor elements 21 are all the same type of element. The plurality of first semiconductor elements 21 are, for example, MOSFETs (Metal-Oxide-Semiconductor Field-Effect Transistors). Alternatively, the plurality of first semiconductor elements 21 may be field-effect transistors including MISFETs (Metal-Insulator-Semiconductor Field-Effect Transistors) or bipolar transistors such as IGBTs (Insulated Gate Bipolar Transistors). In the description of semiconductor device A10, the plurality of first semiconductor elements 21 are n-channel type and specifically refer to vertically structured MOSFETs. The plurality of first semiconductor elements 21 include a compound semiconductor substrate. The composition of the compound semiconductor substrate includes silicon carbide (SiC). The plurality of first semiconductor elements 21 are arranged along a second direction x.

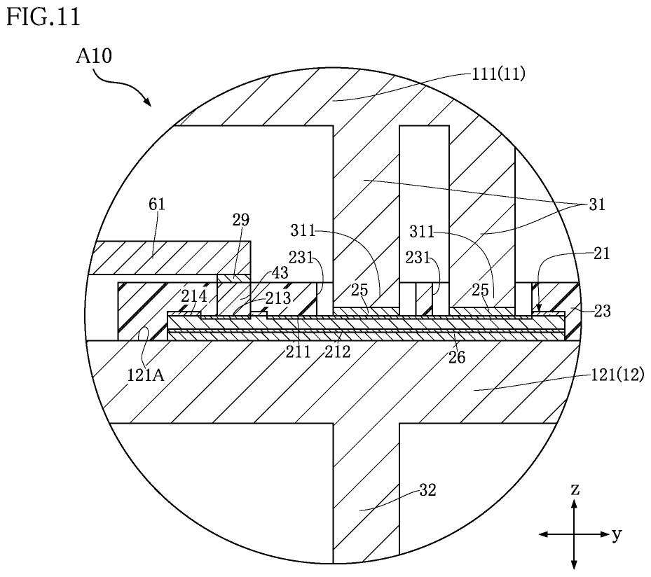

As shown in FIG. 11, each of the plurality of first semiconductor elements 21 has a first electrode 211, a second electrode 212, a first gate electrode 213, and a first protective film 214.

As shown in FIG. 11, the first electrode 211 faces the first base portion 111 of the first terminal 11. The first electrode 211 is conductively connected to the first terminal 11. A current corresponding to the power after the conversion by the first semiconductor element 21 flows through the first electrode 211. That is, the first electrode 211 corresponds to the source of the first semiconductor element 21. The first electrode 211 contacts the first flow path 541 within the hollow portion 54 of the housing 50.

As shown in FIG. 11, the second electrode 212 faces the first mounting surface 121A of the second base portion 121 of the second terminal 12. The second electrode 212 is electrically connected to the second terminal 12. A current corresponding to the power before conversion by the first semiconductor element 21 flows through the second electrode 212. That is, the second electrode 212 corresponds to the drain of the first semiconductor element 21.

As shown in FIG. 11, the first gate electrode 213 is positioned on the same side as the first electrode 211 in the first direction z. A gate voltage for driving the first semiconductor element 21 is applied to the first gate electrode 213. As shown in FIG. 5, viewed in the first direction z, the area of the first gate electrode 213 is smaller than the area of the first electrode 211.

As shown in FIG. 11, the first protective film 214 is positioned on the same side as the first electrode 211 in the first direction z. Viewed in the first direction z, the first protective film 214 surrounds the periphery of both the first electrode 211 and the first gate electrode 213. The first protective film 214 is an insulator. The first protective film 214 is a stack of, for example, a layer of silicon dioxide (SiO₂), a layer of silicon nitride (Si₃N₄) and a layer of polybenzoxazole (PBO) disposed in this order. Note that in the first protective film 214, the polybenzoxazole layer may be replaced with a polyimide layer.

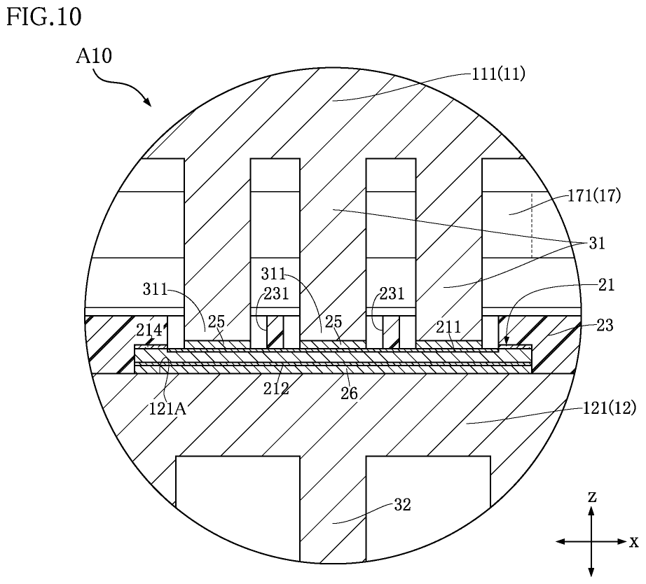

The second bonding layer 26, as shown in FIGS. 10 and 11, conductively bonds the first mounting surface 121A of the second base portion 121 of the second terminal 12 to the second electrode 212 of each of the plurality of first semiconductor elements 21. Thus, the second electrode 212 of each of the plurality of first semiconductor elements 21 is conductively connected to the second terminal 12. The second bonding layer 26 is solder. Alternatively, the second bonding layer 26 may be a sintered metal containing silver (Ag), or the like.

Each of the plurality of first protective layers 23, as shown in FIGS. 5 and 7 to 9, covers a portion of one of the plurality of first semiconductor elements 21. The plurality of first protective layers 23 are insulators. The plurality of first protective layers 23 are made of a material including, for example, epoxy resin. As shown in FIG. 5, viewed in the first direction z, each of the plurality of first protective layers 23 covers the entire periphery of one of the plurality of first semiconductor elements 21. As shown in FIGS. 10 and 11, each of the plurality of first protective layers 23 covers a portion of the first protective film 214 of one of the plurality of first semiconductor elements 21.

As shown in FIGS. 5, 10, and 11, a plurality of first openings 231 are provided in each of the plurality of first protective layers 23. The plurality of first openings 231 are provided on a side opposite in the first direction z to the side facing the first mounting surface 121A of the second base portion 121 of the second terminal 12. A first electrode 211 of one of the plurality of first semiconductor elements 21 is exposed from each of the plurality of first openings 231.

As shown in FIGS. 10 and 11, each of the plurality of first protective layers 23 contacts the first mounting surface 121A of the second base portion 121 of the second terminal 12. The second bonding layer 26 contacts one of the plurality of first protective layers 23.

The plurality of second semiconductor elements 22 are, as shown in FIGS. 7 to 9, positioned on a side opposite in the first direction z to the plurality of first semiconductor elements 21 with respect to the first terminal 11. Furthermore, the plurality of second semiconductor elements 22 are positioned between the first base portion 111 of the first terminal 11 and the third base portion 131 of the third terminal 13 in the first direction z. The plurality of second semiconductor elements 22 are housed within the third flow path 543 of the hollow portion 54 of the housing 50. Viewed in the first direction z, the plurality of second semiconductor elements 22 individually overlap the plurality of first semiconductor elements 21. The plurality of second semiconductor elements 22 are the same elements as the plurality of first semiconductor elements 21. Therefore, the plurality of second semiconductor elements 22 are n-channel type and are vertical structure MOSFETs. The plurality of second semiconductor elements 22 are arranged along the second direction x.

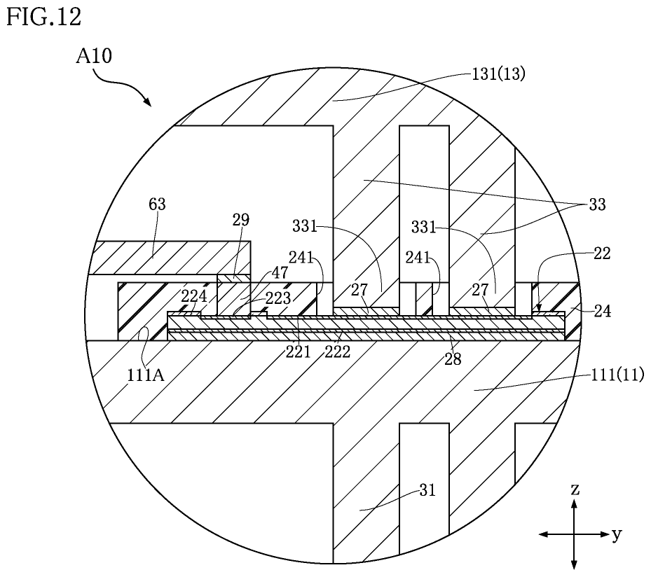

As shown in FIG. 12, each of the plurality of second semiconductor elements 22 has a third electrode 221, a fourth electrode 222, a second gate electrode 223, and a second protective film 224.

As shown in FIG. 12, the third electrode 221 faces the third base portion 131 of the third terminal 13. The third electrode 221 is conductively connected to the third terminal 13. A current corresponding to the power after conversion by the second semiconductor element 22 flows through the third electrode 221. That is, the third electrode 221 corresponds to the source of the second semiconductor element 22. The third electrode 221 contacts the third flow path 543 within the hollow portion 54 of the housing 50.

As shown in FIG. 12, the fourth electrode 222 faces the second mounting surface 111A of the first base portion 111 of the first terminal 11. The fourth electrode 222 is electrically connected to the first terminal 11. A current corresponding to the power before conversion by the second semiconductor element 22 flows through the fourth electrode 222. That is, the fourth electrode 222 corresponds to the drain of the second semiconductor element 22.

As shown in FIG. 12, the second gate electrode 223 is positioned on the same side as the third electrode 221 in the first direction z. A gate voltage for driving the second semiconductor element 22 is applied to the second gate electrode 223. As shown in FIG. 3, viewed in the first direction z, the area of the second gate electrode 223 is smaller than the area of the third electrode 221.

As shown in FIG. 12, the second protective film 224 is positioned on the same side as the third electrode 221 in the first direction z. Viewed in the first direction z, the second protective film 224 surrounds the periphery of both the third electrode 221 and the second gate electrode 223. The second protective film 224 is an insulator. The composition of the second protective film 224 is identical to the composition of the respective first protective films 214 of the plurality of first semiconductor elements 21.

The fourth bonding layer 28, as shown in FIG. 12, conductively bonds the second mounting surface 111A of the first base portion 111 of the first terminal 11 to the fourth electrode 222 of each of the plurality of second semiconductor elements 22. Consequently, the fourth electrode 222 of each of the plurality of second semiconductor elements 22 is conductively connected to the first terminal 11. The fourth bonding layer 28 is solder. Alternatively, the fourth bonding layer 28 may be a sintered metal containing silver or the like.

Each of the plurality of second protective layers 24 covers, as shown in FIGS. 3 and 7 to 9, a portion of one of the plurality of second semiconductor elements 22. The plurality of second protective layers 24 are insulators. The plurality of second protective layers 24 are made of a material including, for example, epoxy resin. As shown in FIG. 3, viewed in the first direction z, each of the plurality of second protective layers 24 covers the entire periphery of one of the plurality of second semiconductor elements 22. As shown in FIG. 12, each of the plurality of second protective layers 24 covers a portion of the second protective film 224 of one of the plurality of second semiconductor elements 22.

As shown in FIGS. 3 and 12, a plurality of second openings 241 are provided in each of the plurality of second protective layers 24. The plurality of second openings 241 are provided on a side opposite in the first direction z to the side facing the second mounting surface 111A of the first base portion 111 of the first terminal 11. A third electrode 221 of one of the plurality of second semiconductor elements 22 is exposed from each of the plurality of second openings 241.

As shown in FIG. 12, each of the plurality of second protective layers 24 contacts the second mounting surface 111A of the first base portion 111 of the first terminal 11. The fourth bonding layer 28 contacts one of the plurality of second protective layers 24.

A plurality of first gate pillars 43 are, as shown in FIG. 11, individually and electrically connected to the first gate electrode 213 of each of the plurality of first semiconductor elements 21. The plurality of first gate pillars 43 contain, for example, copper. The plurality of first gate pillars 43 are formed, for example, by plating. One side in the first direction z of each of the plurality of first gate pillars 43 is exposed from one of the plurality of first protective layers 23.

The plurality of first detection pillars 44 are, as shown in FIG. 5, individually and electrically connected to the first electrode 211 of each of the plurality of first semiconductor elements 21. The plurality of first detection pillars 44 contain, for example, copper. The plurality of first detection pillars 44 are formed, for example, by plating. One side in the first direction z of each of the plurality of first detection pillars 44 is exposed from one of the plurality of first protective layers 23.

A plurality of second gate pillars 47 are, as shown in FIG. 12, individually and electrically connected to the second gate electrode 223 of each of the plurality of second semiconductor elements 22. The plurality of second gate pillars 47 contain, for example, copper. The plurality of second gate pillars 47 are formed, for example, by plating. One side in the first direction z of each of the plurality of second gate pillars 47 is exposed from one of the plurality of second protective layers 24.

The plurality of second detection pillars 48 are, as shown in FIG. 3, individually and electrically connected to the third electrode 221 of each of the plurality of second semiconductor elements 22. The plurality of second detection pillars 48 contain, for example, copper. The plurality of second detection pillars 48 are formed, for example, by plating. One side in the first direction z of each of the plurality of second detection pillars 48 is exposed from one of the plurality of second protective layers 24.

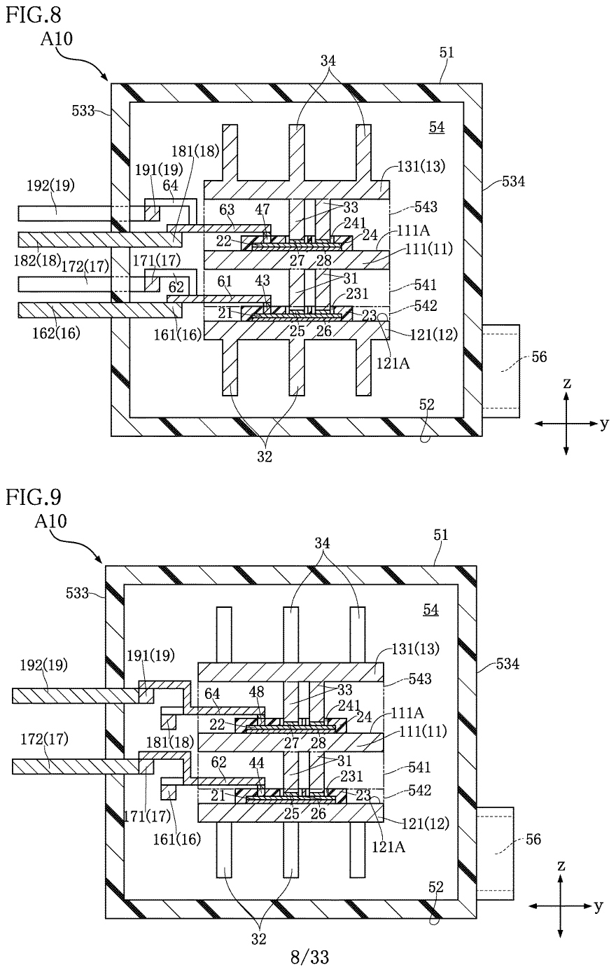

The first signal terminal 16 is, as shown in FIGS. 4 and 5, positioned on one side in the third direction y of the first terminal 11 and the second terminal 12. The first signal terminal 16 is supported by the housing 50. The first signal terminal 16 is electrically connected to the first gate electrode 213 of each of the plurality of first semiconductor elements 21. A gate voltage for driving the plurality of first semiconductor elements 21 is applied to the first signal terminal 16. The first signal terminal 16 is, for example, a metal lead containing copper. The first signal terminal 16 has an inner portion 161 and an outer portion 162. The inner portion 161 is housed within the housing 50. Furthermore, a portion of the inner portion 161 is housed within the hollow portion 54 of the housing 50. The inner portion 161 includes a portion extending in the second direction x. The outer portion 162 is connected to the inner portion 161. As shown in FIG. 8, the outer portion 162 protrudes outward from the third side surface 533 of the housing 50.

Each of the plurality of first leads 61 is electrically connected to one of the first gate electrodes 213 of the plurality of first semiconductor elements 21 and to the first signal terminal 16. As shown in FIG. 5, each of the plurality of first leads 61 extends in the third direction y. As shown in FIG. 8, a portion of each of the plurality of first leads 61 is housed within the first flow path 541 of the hollow portion 54 of the housing 50. The plurality of first leads 61 are, for example, metal leads containing copper. As shown in FIG. 11, one side in the third direction y of the plurality of first leads 61 is conductively bonded to one of the plurality of first gate pillars 43 via the fifth bonding layer 29. The fifth bonding layer 29 is solder. Alternatively, the fifth bonding layer 29 may be a sintered metal containing silver, or the like. The other side in the third direction y of each of the plurality of first leads 61 is conductively bonded to the inner portion 161 of the first signal terminal 16.

The second signal terminal 17 is, as shown in FIGS. 4 and 5, positioned on the same side as the first signal terminal 16 with respect to the first terminal 11 and the second terminal 12 in the third direction y. The second signal terminal 17 is supported by the housing 50. The second signal terminal 17 is electrically connected to the first electrode 211 of each of the plurality of first semiconductor elements 21. A voltage at the same potential as the voltage applied to the first electrode 211 of each of the plurality of first semiconductor elements 21 is applied to the second signal terminal 17. The second signal terminal 17 is, for example, a metal lead containing copper. The second signal terminal 17 has an inner portion 171 and an outer portion 172. The inner portion 171 is housed within the housing 50. Furthermore, a portion of the inner portion 171 is housed within the hollow portion 54 of the housing 50. The inner portion 171 includes a portion extending in the second direction x. As shown in FIGS. 8 and 9, the inner portion 171 is positioned closer to the top surface 51 of the housing 50 than the inner portion 161 of the first signal terminal 16 is. The outer portion 172 is connected to the inner portion 171. As shown in FIG. 9, the outer portion 172 protrudes outward from the third side surface 533 of the housing 50.

Each of the plurality of second leads 62 is electrically connected to one of the first electrodes 211 of the plurality of first semiconductor elements 21 and to the second signal terminal 17. As shown in FIG. 5, viewed in the first direction z, each of the plurality of second leads 62 extends in the third direction y. As shown in FIG. 9, each of the plurality of second leads 62 spans over the inner portion 161 of the first signal terminal 16. A portion of each of the plurality of second leads 62 is housed within the first flow path 541 of the hollow portion 54 of the housing 50. The plurality of second leads 62 are, for example, metal leads containing copper. One end in the third direction y of each of the plurality of second leads 62 is conductively bonded to one of the plurality of first detection pillars 44. The other end in the third direction y of each of the plurality of second leads 62 is conductively bonded to the inner portion 171 of the second signal terminal 17.

The third signal terminal 18 is, as shown in FIGS. 2 and 3, positioned on one side in the third direction y with respect to the first terminal 11 and the third terminal 13. Viewed in the first direction z, the third signal terminal 18 overlaps the first signal terminal 16. The third signal terminal 18 is supported by the housing 50. The third signal terminal 18 is conductively connected to the second gate electrode 223 of each of the plurality of second semiconductor elements 22. A gate voltage for driving the plurality of second semiconductor elements 22 is applied to the third signal terminal 18. The third signal terminal 18 is, for example, a metal lead containing copper. The third signal terminal 18 has an inner portion 181 and an outer portion 182. The inner portion 181 is housed within the housing 50. Furthermore, a portion of the inner portion 181 is housed within the hollow portion 54 of the housing 50. The inner portion 181 includes a portion extending in the second direction x. The outer portion 182 is connected to the inner portion 181. As shown in FIG. 8, the outer portion 182 protrudes outward from the third side surface 533 of the housing 50.

Each of the plurality of third leads 63 is electrically connected to one of the second gate electrodes 223 of the plurality of second semiconductor elements 22 and to the third signal terminal 18. As shown in FIG. 3, each of the plurality of third leads 63 extends in a third direction y. As shown in FIG. 8, a portion of each of the plurality of third leads 63 is housed within a third flow path 543 of the hollow portion 54 of the housing 50. The plurality of third leads 63 are, for example, metal leads containing copper. As shown in FIG. 12, one side in the third direction y of each of the plurality of third leads 63 is conductively bonded to one of the plurality of second gate pillars 47 via the fifth bonding layer 29. The other side in the third direction y of each of the plurality of third leads 63 is conductively bonded to the inner portion 181 of the third signal terminal 18.

The fourth signal terminal 19 is, as shown in FIGS. 2 and 3, positioned on the same side as the third signal terminal 18 with respect to the first terminal 11 and the third terminal 13 in the third direction y. Viewed in the first direction z, the fourth signal terminal 19 overlaps with the second signal terminal 17. The fourth signal terminal 19 is supported by the housing 50. The fourth signal terminal 19 is electrically connected to the third electrode 221 of each of the plurality of second semiconductor elements 22. A voltage at the same potential as the voltage applied to the third electrode 221 of each of the plurality of second semiconductor elements 22 is applied to the fourth signal terminal 19. The fourth signal terminal 19 is, for example, a metal lead containing copper. The fourth signal terminal 19 has an inner portion 191 and an outer portion 192. The inner portion 191 is housed within the housing 50. Furthermore, a portion of the inner portion 191 is housed within the hollow portion 54 of the housing 50. The inner portion 191 includes a part extending in the second direction x. As shown in FIGS. 8 and 9, the inner portion 191 is positioned closer to the top surface 51 of the housing 50 than the inner portion 181 of the third signal terminal 18 is. The outer portion 192 is connected to the inner portion 191. As shown in FIG. 9, the outer portion 192 protrudes outward from the third side surface 533 of the housing 50.

Each of the plurality of fourth leads 64 is electrically connected to one of the third electrodes 221 of the plurality of second semiconductor elements 22 and to the fourth signal terminal 19. As shown in FIG. 3, viewed in the first direction z, each of the plurality of fourth leads 64 extends in the third direction y. As shown in FIG. 9, each of the plurality of fourth leads 64 spans over the inner portion 181 of the third signal terminal 18. A portion of each of the plurality of fourth leads 64 is housed within the third flow path 543 of the hollow portion 54 of the housing 50. The plurality of fourth leads 64 are, for example, metal leads containing copper. One end in the third direction y of each of the plurality of fourth leads 64 is conductively bonded to one of the plurality of second detection pillars 48. The other end in the third direction y of each of the plurality of fourth leads 64 is conductively bonded to the inner portion 191 of the fourth signal terminal 19.

A plurality of first heat dissipation members 31 are, as shown in FIGS. 7 to 9, electrically connected to the first base portion 111 of the first terminal 11. The plurality of first heat dissipation members 31 are housed in the first flow path 541 of the hollow portion 54 of the housing 50. The plurality of first heat dissipation members 31 are, for example, rod members containing copper. Each of the plurality of first heat dissipation members 31 extends in a first direction z. In the semiconductor device A10, one side in the first direction z of each of the plurality of first heat dissipation members 31 is conductively bonded to the first base portion 111, for example, by laser welding. As shown in FIGS. 10 and 11, each of the plurality of first heat dissipation members 31 has a first end portion 311 located on the other side in the first direction z. The first end portion 311 of each of the plurality of first heat dissipation members 31 is individually inserted into a respective one of the plurality of first openings 231 of the plurality of first protective layers 23. At each of the plurality of first openings 231, a gap is provided between one of the plurality of first heat dissipation members 31 and one of the plurality of first protective layers 23.

The first bonding layer 25, as shown in FIGS. 10 and 11, conductively bonds the first electrode 211 of each of the plurality of first semiconductor elements 21 to the first end portion 311 of each of the plurality of first heat dissipation members 31. Consequently, the first electrode 211 of each of the plurality of first semiconductor elements 21 is electrically connected to the first terminal 11. The first bonding layer 25 is solder. Alternatively, the first bonding layer 25 may be a sintered metal containing silver or the like.

The plurality of second heat dissipation members 32 are, as shown in FIGS. 7 and 8, connected to the second base portion 121 of the second terminal 12. The plurality of second heat dissipation members 32 are positioned on a side opposite in the first direction z to the plurality of first semiconductor elements 21 with respect to the second terminal 12. The plurality of second heat dissipation members 32 are housed within the hollow portion 54 of the housing 50. The plurality of second heat dissipation members 32 are, for example, rod members containing copper. Each of the plurality of second heat dissipation members 32 extends in the first direction z. In the semiconductor device A10, one side in the first direction z of each of the plurality of second heat dissipation members 32 is conductively bonded to the second base portion 121, for example, by laser welding.

The plurality of third heat dissipation members 33 are, as shown in FIGS. 7 to 9, electrically connected to the third base portion 131 of the third terminal 13. The plurality of third heat dissipation members 33 are housed within the third flow path 543 of the hollow portion 54 of the housing 50. The plurality of third heat dissipation members 33 are, for example, rod members containing copper. Each of the plurality of third heat dissipation members 33 extends in a first direction z. In the semiconductor device A10, one side in the first direction z of each of the plurality of third heat dissipation members 33 is conductively bonded to the third base portion 131, for example, by laser welding. As shown in FIG. 12, each of the plurality of third heat dissipation members 33 has a second end portion 331 located on the other side in the first direction z. The second end portion 331 of each of the plurality of third heat dissipation members 33 is individually inserted into each of the plurality of second openings 241 of the plurality of second protective layers 24. At each of the plurality of second openings 241, a gap is provided between a second end portion 331 of one of the plurality of third heat dissipation members 33 and one of the plurality of second protective layers 24.

The third bonding layer 27, as shown in FIG. 12, conductively bonds the third electrode 221 of each of the plurality of second semiconductor elements 22 to the second end portion 331 of each of the plurality of third heat dissipation members 33. Consequently, the third electrode 221 of each of the plurality of second semiconductor elements 22 is conductively connected to the third terminal 13. The third bonding layer 27 is solder. Alternatively, the third bonding layer 27 may be a sintered metal containing silver or the like.

The plurality of fourth heat dissipation members 34 are, as shown in FIGS. 7 and 8, connected to the third base portion 131 of the third terminal 13. The plurality of fourth heat dissipation members 34 are positioned on a side opposite in the first direction z to the plurality of second semiconductor elements 22 with respect to the third terminal 13. The plurality of fourth heat dissipation members 34 are housed within the hollow portion 54 of the housing 50. The plurality of fourth heat dissipation members 34 are, for example, rod members containing copper. Each of the plurality of fourth heat dissipation members 34 extends in the first direction z. In the semiconductor device A10, one side in the first direction z of each of the plurality of fourth heat dissipation members 34 is conductively bonded to the third base portion 131, for example, by laser welding.

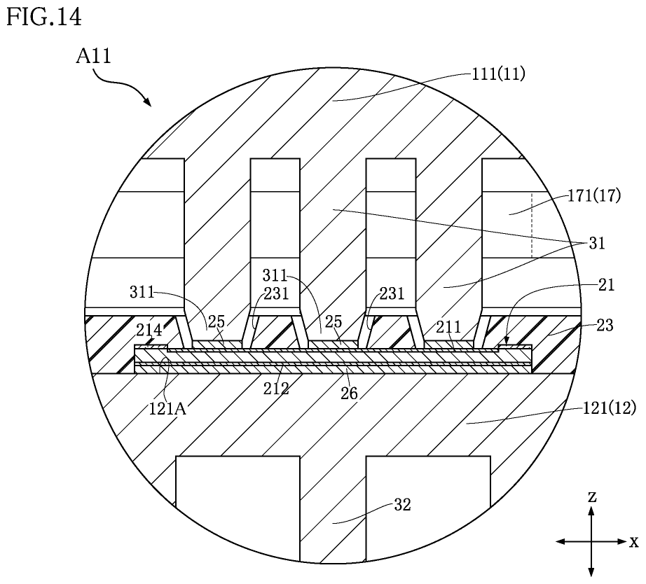

Next, with reference to FIG. 14, a semiconductor device A11 according to a variation of the first embodiment of the present disclosure will be described. Here, FIG. 14 corresponds to FIG. 10.

As shown in FIG. 14, in the semiconductor device A11, the configuration of the plurality of first protective layers 23 and the plurality of first heat dissipation members 31 differs from that in the semiconductor device A10. In each of the plurality of first protective layers 23, the size of the cross-section perpendicular to the first direction z of each of the plurality of first openings 231 expands starting from one first electrode 211 of the plurality of first semiconductor elements 21 toward the first base portion 111 of the first terminal 11. The size of the cross-section perpendicular to the first direction z of the first end portion 311 of each of the plurality of first heat dissipation members 31 expands starting from the first electrode 211 of one of the plurality of first semiconductor elements 21 toward the first base portion 111 of the first terminal 11.

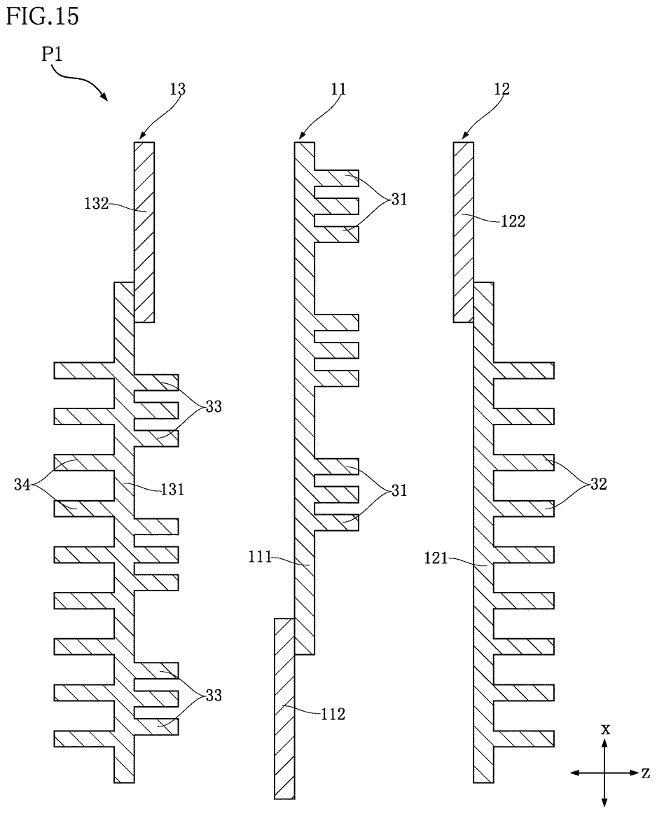

Next, based on FIGS. 15 to 18, an example of a manufacturing method for the semiconductor device A10 will be described.

First, a first process P1 shown in FIG. 15 is performed. In the first process P1, a plurality of first heat dissipation members 31 are conductively bonded to one side in the first direction z of the first base portion 111 of the first terminal 11. In the first process P1, a plurality of second heat dissipation members 32 are conductively bonded to one side in the first direction z of the second base portion 121 of the second terminal 12. Furthermore, in the first process P1, a plurality of third heat dissipation members 33 are conductively bonded to one side in the first direction z of the third base portion 131 of the third terminal 13. Simultaneously, a plurality of fourth heat dissipation members 34 are conductively bonded to the other side in the first direction z of the third base portion 131 of the third terminal 13.

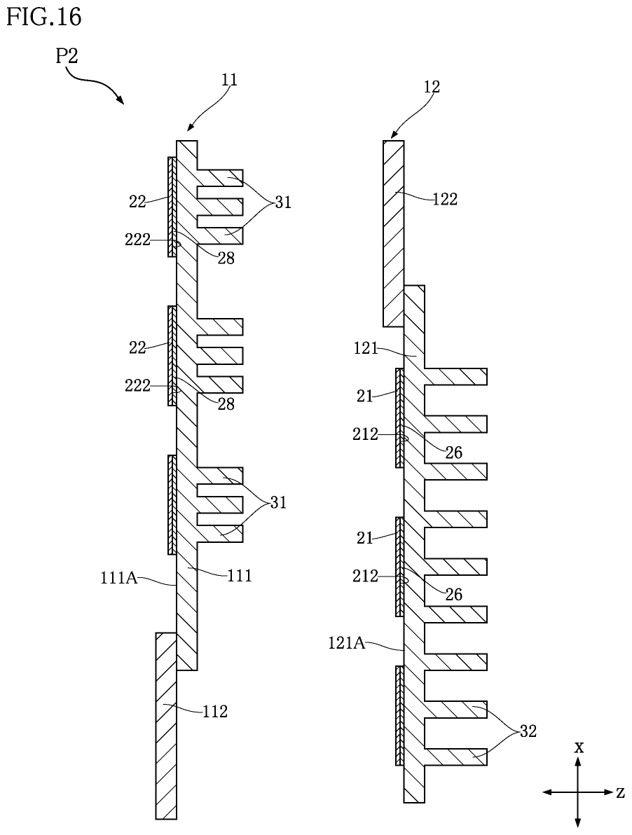

Next, a second process P2 shown in FIG. 16 is performed. In the second process P2, each second electrode 212 of the plurality of first semiconductor elements 21 is conductively bonded to the first mounting surface 121A of the second terminal 12 via the second bonding layer 26. Furthermore, in the second process P2, the fourth electrode 222 of each of the plurality of second semiconductor elements 22 is conductively bonded to the second mounting surface 111A of the first terminal 11 via the fourth bonding layer 28.

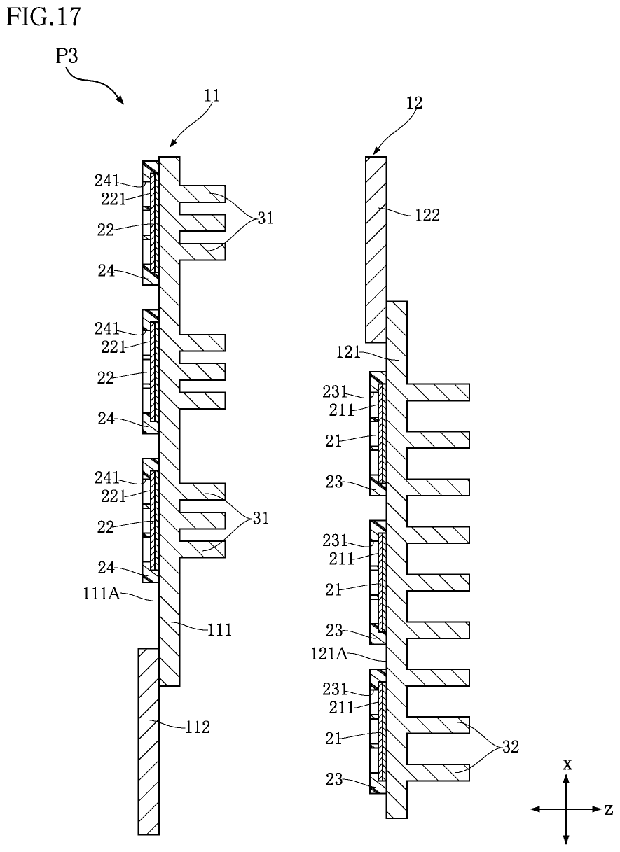

Next, a third process P3 shown in FIG. 17 is performed. In the third process P3, a plurality of first protective layers 23 are formed to cover a portion of each of the plurality of first semiconductor elements 21. The plurality of first protective layers 23 are insulators. The plurality of first protective layers 23 are formed by thermosetting a material containing epoxy resin. Subsequently, the plurality of first openings 231 are formed in each of the plurality of first protective layers 23. The plurality of first openings 231 are formed by laser processing. The first electrode 211 of one of the plurality of first semiconductor elements 21 is exposed from each of the plurality of first openings 231.

As shown in FIG. 17, further in the third process P3, the plurality of second protective layers 24 are formed to cover a portion of each of the plurality of second semiconductor elements 22. The plurality of second protective layers 24 are insulators. The plurality of second protective layers 24 are formed by thermosetting a material containing epoxy resin. Subsequently, the plurality of second openings 241 are formed in each of the plurality of second protective layers 24. The plurality of second openings 241 are formed by laser processing. The third electrode 221 of one of the plurality of second semiconductor elements 22 is exposed from each of the plurality of second openings 241.

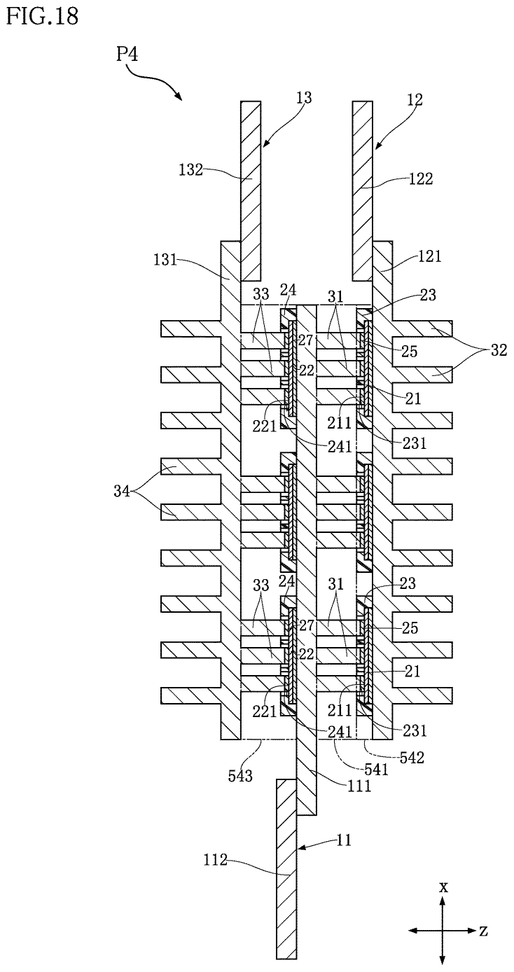

Next, a fourth process P4 shown in FIG. 18 is performed. In the fourth process P4, the first end portion 311 (see FIGS. 10 and 11) of each of the plurality of first heat dissipation members 31 is individually inserted into the plurality of first openings 231 of each of the plurality of first protective layers 23. This conductively bonds each of the plurality of first heat dissipation members 31 to the first electrode 211 of one of the plurality of first semiconductor elements 21 via the first bonding layer 25. At this time, a gap is provided at each of the plurality of first openings 231 between the first end portion 311 of one of the plurality of first heat dissipation members 31 and one of the plurality of first protective layers 23.

As shown in FIG. 18, in the fourth process P4, the second end portion 331 (see FIG. 12) of each of the plurality of third heat dissipation members 33 is individually inserted into the plurality of second openings 241 of each of the plurality of second protective layers 24. This conductively bonds each of the plurality of third heat dissipation members 33 to the third electrode 221 of one of the plurality of second semiconductor elements 22 via the third bonding layer 27. At this time, a gap is provided at each of the plurality of second openings 241 between the second end portion 331 of one of the plurality of third heat dissipation members 33 and one of the plurality of second protective layers 24.

As shown in FIG. 18, further in the fourth process P4, the first flow path 541 is provided between the plurality of first semiconductor elements 21 and the first terminal 11 in the first direction z. The plurality of first heat dissipation members 31 are housed in the first flow path 541.

After undergoing the fourth process P4, the first signal terminal 16, the second signal terminal 17, the third signal terminal 18, and the fourth signal terminal 19 are disposed. Subsequently, each of the plurality of first leads 61, the plurality of second leads 62, the plurality of third leads 63, and the plurality of fourth leads 64 is conductively bonded to a predetermined location. Finally, the housing 50 to support the first terminal 11, the second terminal 12, and the third terminal 13 is assembled. By performing the above steps, the semiconductor device A10 is obtained.

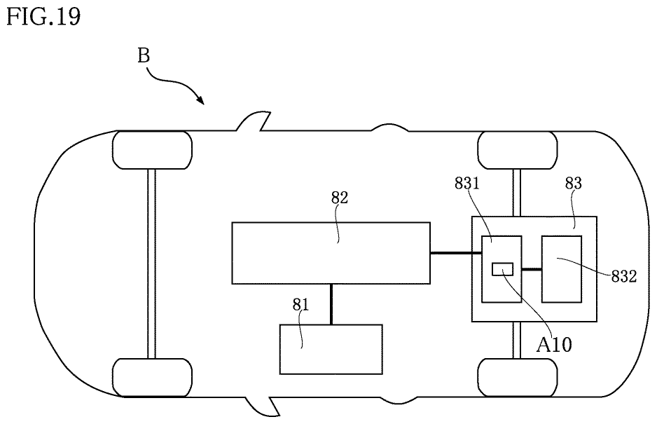

Next, with reference to FIG. 19, a vehicle B equipped with the semiconductor device A10 is described. The vehicle B is, for example, an electric vehicle (EV).

As shown in FIG. 19, the vehicle B includes an onboard charger 81, a storage battery 82, and a drive system 83. The onboard charger 81 receives power wirelessly from a power supply facility (not shown) provided outdoor. Alternatively, a supply means of power from the power supply facility to the onboard charger 81 may be wired. The onboard charger 81 incorporates a boost-type DC-DC converter. The power supplied to the onboard charger 81 is boosted by this converter, and is subsequently supplied to the storage battery 82. The boosted voltage is, for example, 600 V.

The drive system 83 drives the vehicle B. The drive system 83 includes an inverter 831 and a drive source 832. The semiconductor device A10 constitutes a part of the inverter 831. Power stored in the storage battery 82 is supplied to the inverter 831. The power supplied from the storage battery 82 to the inverter 831 is DC power. Additionally, unlike the power system shown in FIG. 19, a boost-type DC-DC converter may be further provided between the storage battery 82 and the inverter 831. The inverter 831 converts DC power into AC power. The inverter 831, including the semiconductor device A10, is connected to the drive source 832. The drive source 832 includes an AC motor and a transmission. When the AC power converted by the inverter 831 is supplied to the drive source 832, the AC motor rotates, and this rotation is transmitted to the transmission. The transmission reduces the rotational speed transmitted from the AC motor as appropriate and then rotates the drive shaft of the vehicle B. This drives the vehicle B. When driving the vehicle B, it is necessary to freely control the rotational speed of the AC motor based on information such as the variation amount of the accelerator pedal. Therefore, the semiconductor device A10 in the inverter 831 is necessary to output the AC power with a suitably varied frequency to correspond to the required rotational speed of the AC motor.

Next, the operational effect of the semiconductor device A10 is described.

The semiconductor device A10 includes the first semiconductor element 21, the first terminal 11, the first heat dissipation member 31, and the first protective layer 23. The first heat dissipation member 31 is electrically connected to the first terminal 11 and is conductively connected to the first electrode 211 of the first semiconductor element 21. In the first direction z, the first flow path 541 is provided between the first semiconductor element 21 and the first terminal 11. The first heat dissipation member 31 is housed within the first flow path 541. By adopting this configuration, as shown in FIG. 13, when the refrigerant 70 is introduced into the hollow portion 54 of the housing 50, the refrigerant 70 flows down into the first flow path 541. This allows the refrigerant 70 to come into direct contact with the first heat dissipation member 31, thereby increasing the cooling efficiency of the semiconductor device A10 compared to conventional methods. Furthermore, at the first opening 231 provided in the first protective layer 23, a gap is provided between the first end portion 311 of the first heat dissipation member 31 inserted into the first opening 231 and the first protective layer 23. This configuration prevents positional deviation of the first heat dissipation member 31 with respect to the first electrode 211, thereby avoiding impedance of electrical conduction between the first heat dissipation member 31 and the first electrode 211. Consequently, this configuration enables further improvement in cooling efficiency for the semiconductor device A10.

In semiconductor device A10, the presence of a first protective layer 23 enables protection of the first semiconductor element 21 against external factors. In this case, from the perspective of protecting the first semiconductor element 21, it is preferable that the first protective layer 23 covers the entire periphery of the first semiconductor element 21 as viewed in the first direction z. Furthermore, by configuring the first protective layer 23 to cover a portion of the first protective film 214, leakage current from the first semiconductor element 21 can be effectively suppressed.

The first terminal 11 is in contact with the first flow path 541. This configuration allows the refrigerant 70 to directly contact the first terminal 11 as well, thereby further improving the cooling efficiency of the semiconductor device A10.

The first electrode 211 of the first semiconductor element 21 contacts the first flow path 541. This configuration allows refrigerant 70 to directly contact the first electrode 211, further improving the cooling efficiency of semiconductor device A10. In this case, the size of the cross-section orthogonal to the first direction z of the first opening 231 of the first protective layer 23 expands starting from the first electrode 211 toward the first heat dissipation member 31. This configuration facilitates the inflow of refrigerant 70 into the first opening 231, making it easier for refrigerant 70 to come into direct contact not only with the first electrode 211 but also with the first end portion 311 of the first heat dissipation member 31.

The semiconductor device A10 further includes a second terminal 12. The first semiconductor element 21 is electrically connected to the second terminal 12. In the first direction z, the second flow path 542, connected to the first flow path 541, is provided between the second terminal 12 and the first flow path 541. The second terminal 12 contacts the second flow path 542. This configuration allows refrigerant 70 to directly contact the second terminal 12, thereby further improving the cooling efficiency of the semiconductor device A10.

The semiconductor device A10 further includes a housing 50 supporting the first terminal 11, the second terminal 12, and the third terminal 13. The housing 50 is provided with the inlet 55 and the outlet 56. The inlet 55 and the outlet 56 are positioned on sides opposite to each other with respect to the first heat dissipation member 31 in a direction orthogonal to the first direction z. This configuration allows the refrigerant 70 to flow downward, facilitating direct contact between the refrigerant 70 and the first heat dissipation member 31.

In the semiconductor device A11, the size of the cross-section perpendicular to the first direction z of the first opening 231 of the first protective layer 23, and the size of the cross-section perpendicular to the first direction z of the first end portion 311 of the first heat dissipation member 31 are enlarged from the first electrode 211 of the first semiconductor element 21 toward the first terminal 11. By adopting this configuration, in the fourth process P4 shown in FIG. 18, the first end portion 311 can be inserted more smoothly into the first opening 231.

### Second Embodiment

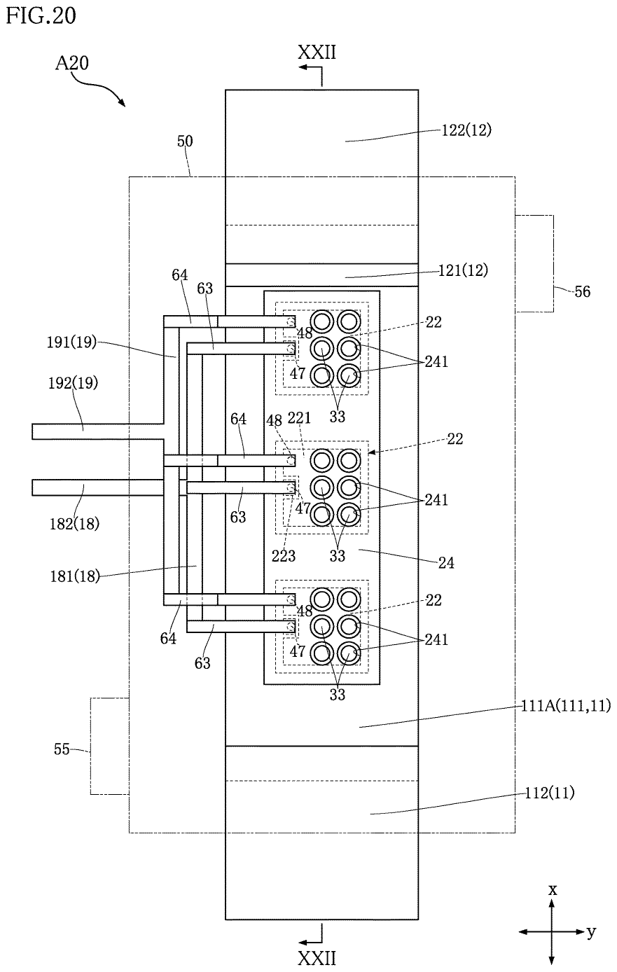

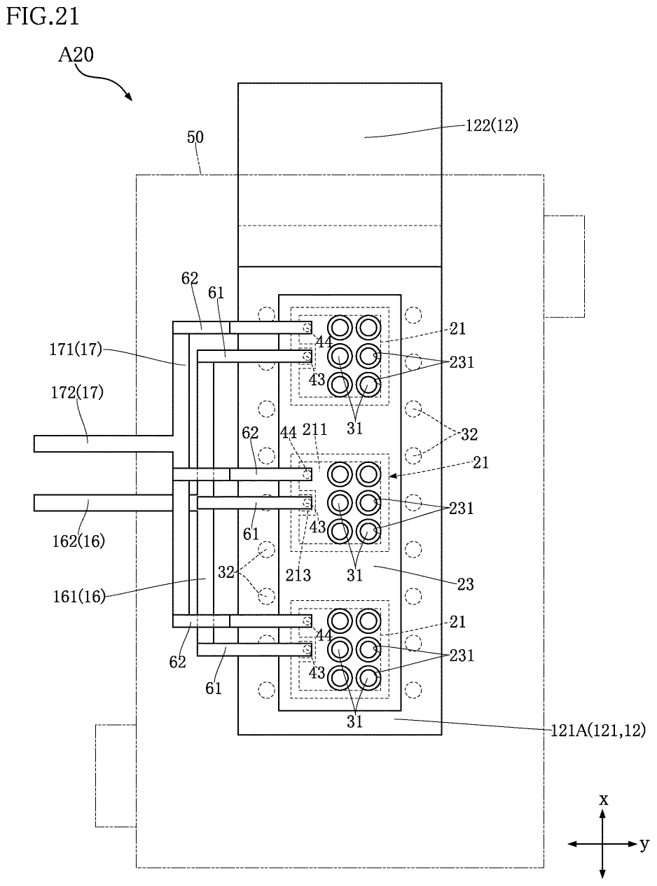

Based on FIGS. 20 to 22, a semiconductor device A20 according to a second embodiment of the present disclosure is described. In these figures, the elements identical or similar to those described above for the semiconductor device A10 are designated by the same reference numerals, and redundant descriptions are omitted. Here, FIG. 20 corresponds to FIG. 3 showing the semiconductor device A10. FIG. 21 corresponds to FIG. 5 showing the semiconductor device A10.

In the semiconductor device A20, the configuration of the plurality of first protective layers 23 and the plurality of second protective layers 24 differs from the corresponding configuration of semiconductor device A10.

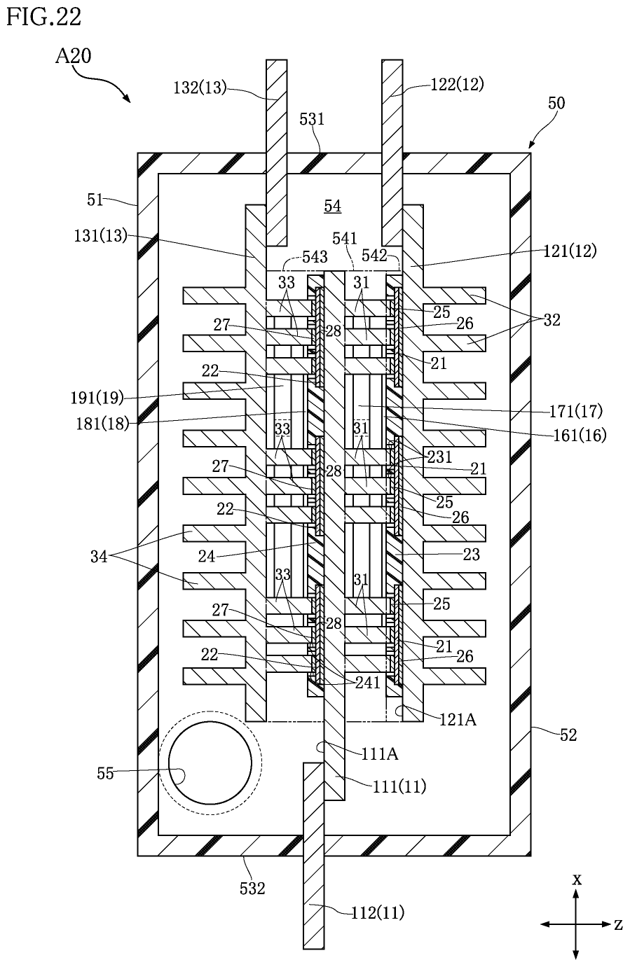

As shown in FIGS. 21 and 22, the plurality of first protective layers 23 form a single member interconnected in the second direction x. As shown in FIGS. 20 and 22, the plurality of second protective layers 24 also form a single member interconnected in the second direction x.

Next, the operational effect of the semiconductor device A20 will be described.

The semiconductor device A20 includes the first semiconductor element 21, the first terminal 11, the first heat dissipation member 31, and the first protective layer 23. The first heat dissipation member 31 is electrically connected to the first terminal 11 and is conductively connected to the first electrode 211 of the first semiconductor element 21. In the first direction z, the first flow path 541 is provided between the first semiconductor element 21 and the first terminal 11. The first heat dissipation member 31 is housed within the first flow path 541. Furthermore, at the first opening 231 provided in the first protective layer 23, a gap is provided between the first end portion 311 of the first heat dissipation member 31 inserted into the first opening 231 and the first protective layer 23. Therefore, according to this configuration, it is possible to further improve the cooling efficiency in the semiconductor device A20 as well. Moreover, the semiconductor device A20 has the configurations common to the semiconductor device A10, thereby achieving the operational effects equivalents to those of the semiconductor device A10.

In the semiconductor device A20, the plurality of first protective layers 23 form the single interconnected member. This configuration allows the plurality of first semiconductor elements 21 to be encapsulated by a single first protective layer 23. Consequently, during the manufacturing of the semiconductor device A20, misalignment of the plurality of first semiconductor elements 21 with respect to each of the first terminal 11 and the second terminal 12 can be suppressed.

### Third Embodiment

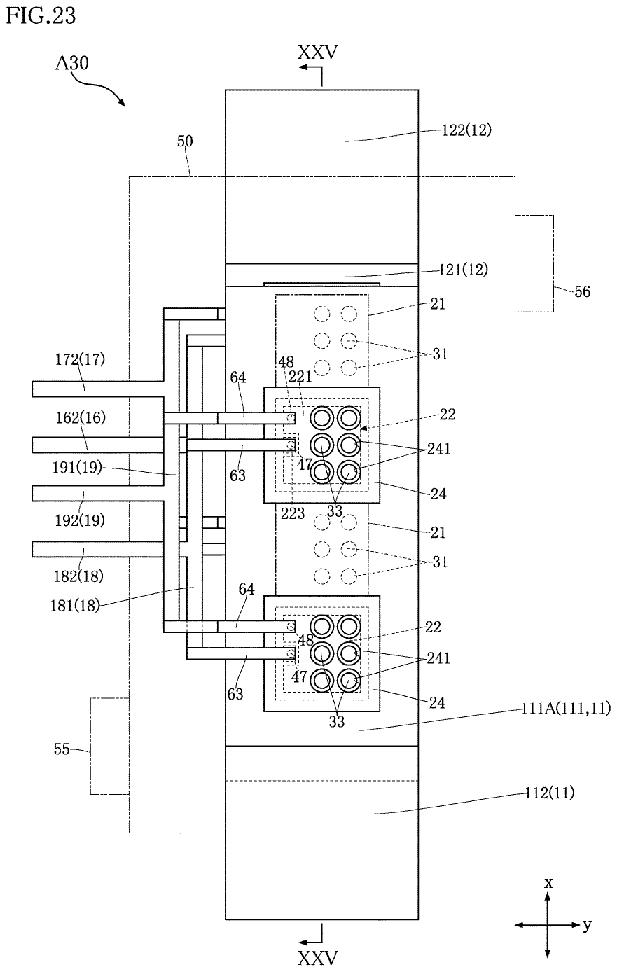

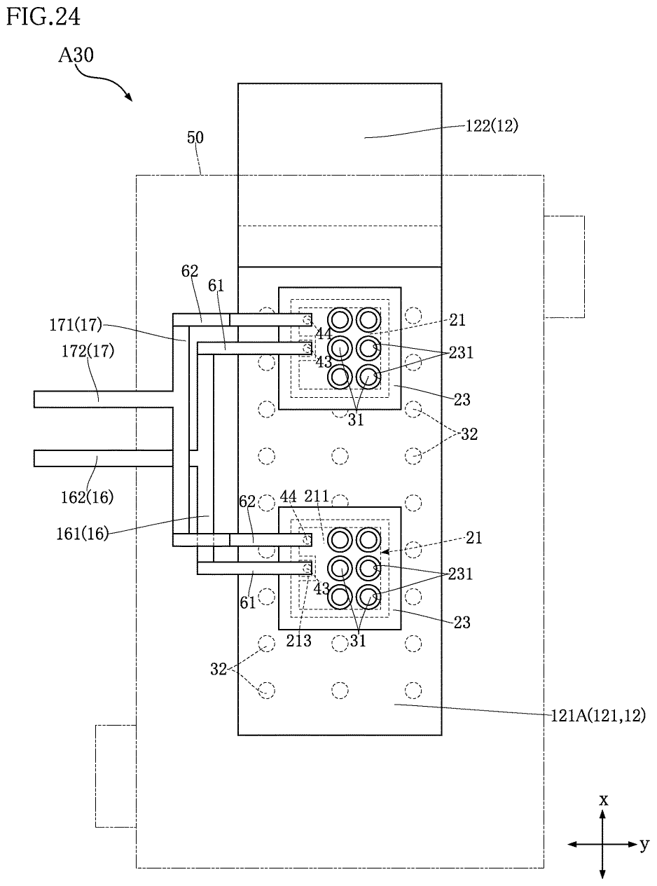

Based on FIGS. 23 to 25, a semiconductor device A30 according to a third embodiment of the present disclosure is described. In these figures, the elements identical or similar to those described above for the semiconductor device A10 are designated by the same reference numerals, and redundant descriptions are omitted. Here, FIG. 23 corresponds to FIG. 3 showing the semiconductor device A10. FIG. 24 corresponds to FIG. 5 showing the semiconductor device A10.

In the semiconductor device A30, the configuration of the plurality of first semiconductor elements 21 and the configuration of the plurality of second semiconductor elements 22 differ from the corresponding configuration of the semiconductor device A10.

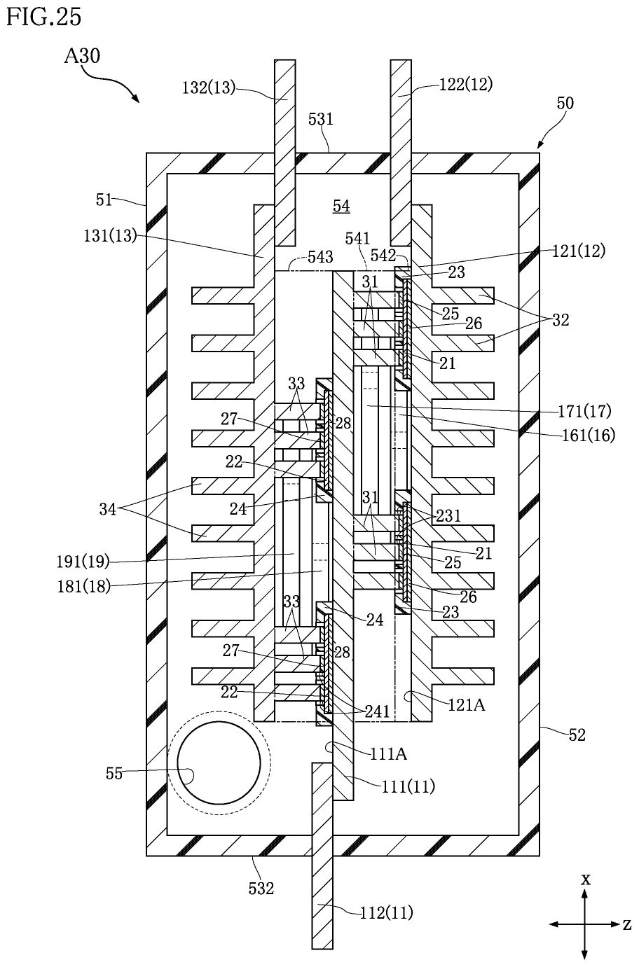

As shown in FIGS. 23 and 24, the number of the plurality of first semiconductor elements 21 and the number of the plurality of second semiconductor elements 22 are both two. As shown in FIGS. 23 and 25, viewed in the first direction z, each of the plurality of second semiconductor elements 22 is separated from the plurality of first semiconductor elements 21.

Next, the operational effect of the semiconductor device A30 will be described.

The semiconductor device A30 includes the first semiconductor element 21, the first terminal 11, the first heat dissipation member 31, and the first protective layer 23. The first heat dissipation member 31 is electrically connected to the first terminal 11 and is conductively connected to the first electrode 211 of the first semiconductor element 21. In the first direction z, the first flow path 541 is provided between the first semiconductor element 21 and the first terminal 11. The first heat dissipation member 31 is housed within the first flow path 541. Furthermore, at the first opening 231 provided in the first protective layer 23, a gap is provided between the first end portion 311 of the first heat dissipation member 31 inserted into the first opening 231 and the first protective layer 23. Therefore, according to this configuration, it is possible to further improve the cooling efficiency in the semiconductor device A30 as well. Moreover, the semiconductor device A30 has the configurations common to those of the semiconductor device A10, thereby achieving the operational effects equivalent to those of the semiconductor device A10.

In the semiconductor device A30, viewed in the first direction z, the second semiconductor element 22 is spaced apart from the first semiconductor element 21. Adopting this configuration reduces the concentration of thermal distribution at the first terminal 11 caused by the heat generation from both the first semiconductor element 21 and the second semiconductor element 22.

### Fourth Embodiment

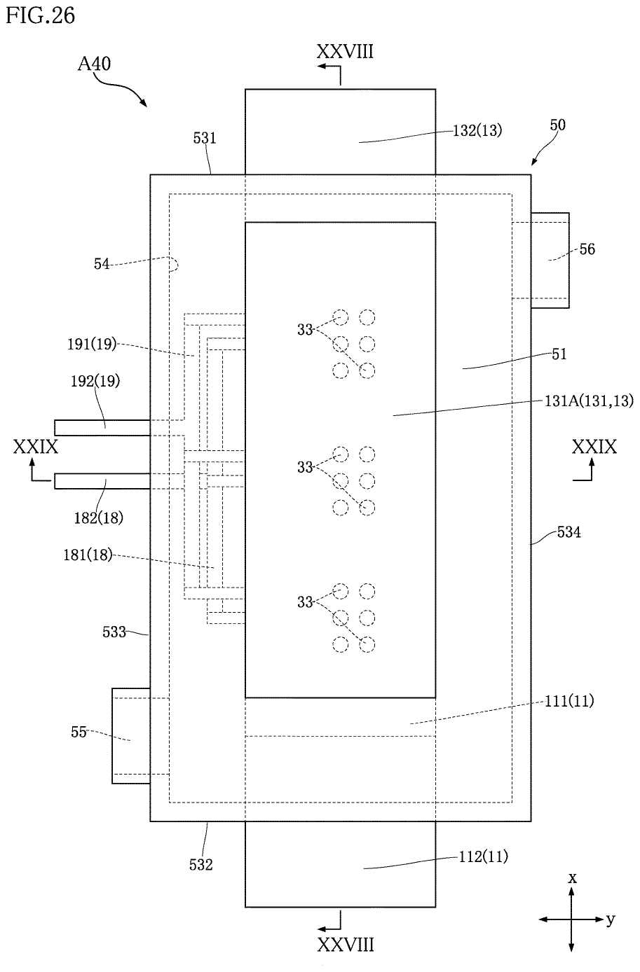

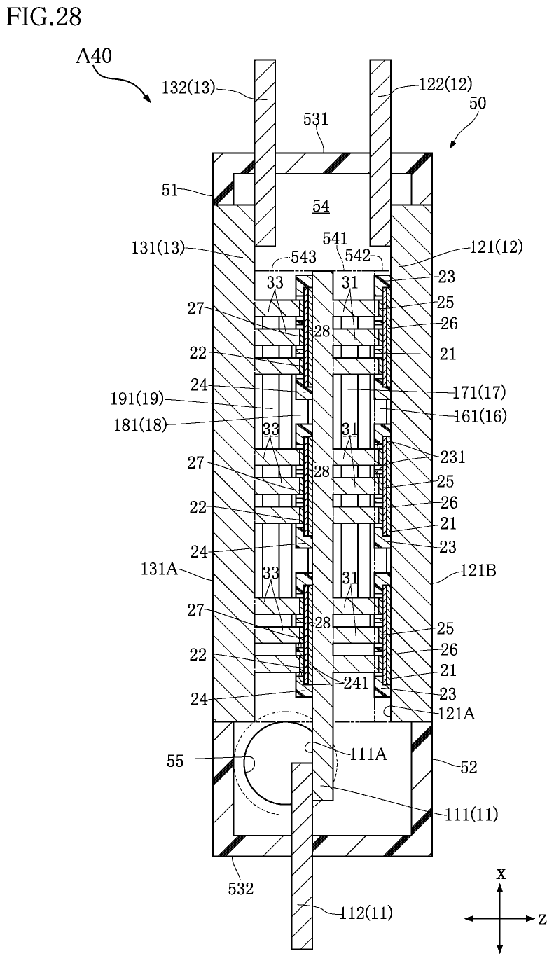

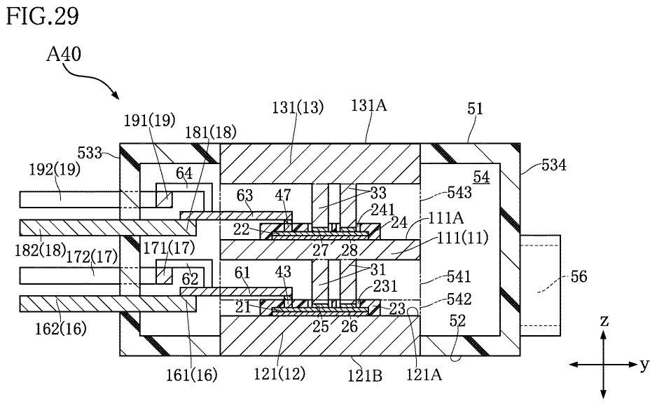

Based on FIGS. 26 to 29, a semiconductor device A40 according to a fourth embodiment of the present disclosure is described. In these figures, the elements identical or similar to those described above for the semiconductor device A10 are designated by the same reference numerals, and redundant descriptions are omitted.

In the semiconductor device A40, the configuration of the second terminal 12 and the third terminal 13 differs from that of the semiconductor device A10. Furthermore, the semiconductor device A40 does not include the plurality of second heat dissipation members 32 and the plurality of fourth heat dissipation members 34.

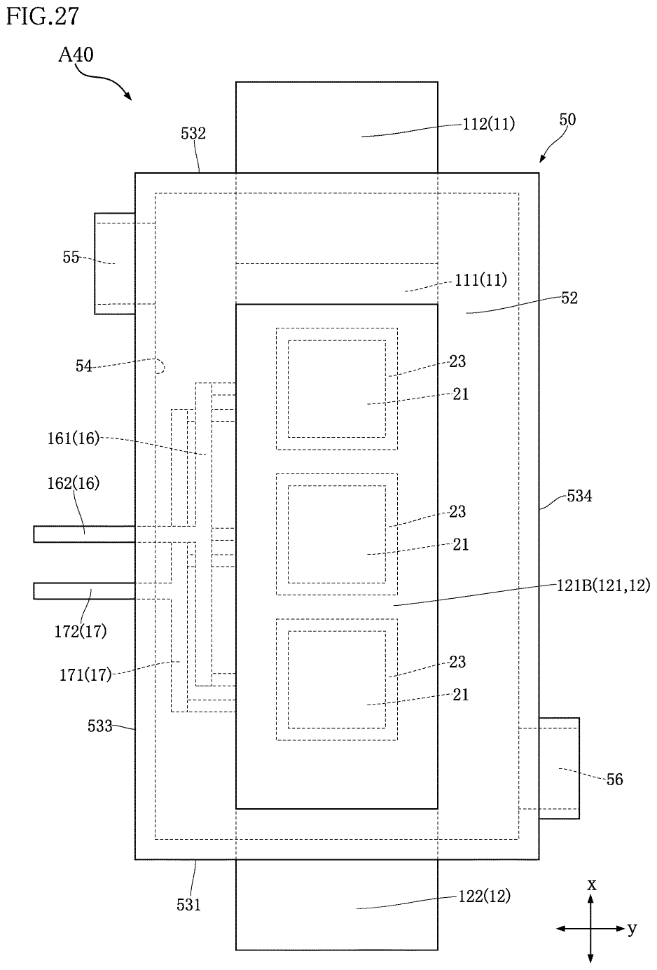

As shown in FIGS. 27 to 29, the second base portion 121 of the second terminal 12 has a first exposed surface 121B facing a side opposite in the first direction z to the side where the plurality of first semiconductor elements 21 are positioned. The first exposed surface 121B is exposed from the bottom surface 52 of the housing 50. The dimension in the first direction z of the second base portion 121 is larger than the dimension in the first direction z of the first base portion 111 of the first terminal 11.

As shown in FIGS. 26, 28, and 29, the third base portion 131 of the third terminal 13 has a second exposed surface 131A facing a side opposite in the first direction z to the side where the plurality of second semiconductor elements 22 are positioned. The second exposed surface 131A is exposed from the top surface 51 of the housing 50. The dimension in the first direction z of the third base portion 131 is larger than the dimension in the first direction z of the first base portion 111 of the first terminal 11.

Next, the operational effect of the semiconductor device A40 will be described.

The semiconductor device A40 includes the first semiconductor element 21, the first terminal 11, the first heat dissipation member 31, and the first protective layer 23. The first heat dissipation member 31 is electrically connected to the first terminal 11 and is conductively connected to the first electrode 211 of the first semiconductor element 21. In the first direction z, the first flow path 541 is provided between the first semiconductor element 21 and the first terminal 11. The first heat dissipation member 31 is housed within the first flow path 541. Furthermore, at the first opening 231 provided in the first protective layer 23, a gap is provided between the first end portion 311 of the first heat dissipation member 31 inserted into the first opening 231 and the first protective layer 23. Therefore, according to this configuration, it is possible to further improve the cooling efficiency in the semiconductor device A40 as well. Moreover, the semiconductor device A40 has the configurations common to those of the semiconductor device A10, thereby achieving the operational effects equivalent to those of the semiconductor device A10.

In the semiconductor device A40, second terminal 12 has the first exposed surface 121B facing a side opposite in the first direction z to the side where first semiconductor element 21 is located. The third terminal 13 has the second exposed surface 131A facing a side opposite in the first direction z to the side where the second semiconductor element 22 is positioned. The first exposed surface 121B and the second exposed surface 131A are exposed from the housing 50. This configuration enables a further reduction in the dimension in the first direction z of the semiconductor device A40.

### Fifth Embodiment

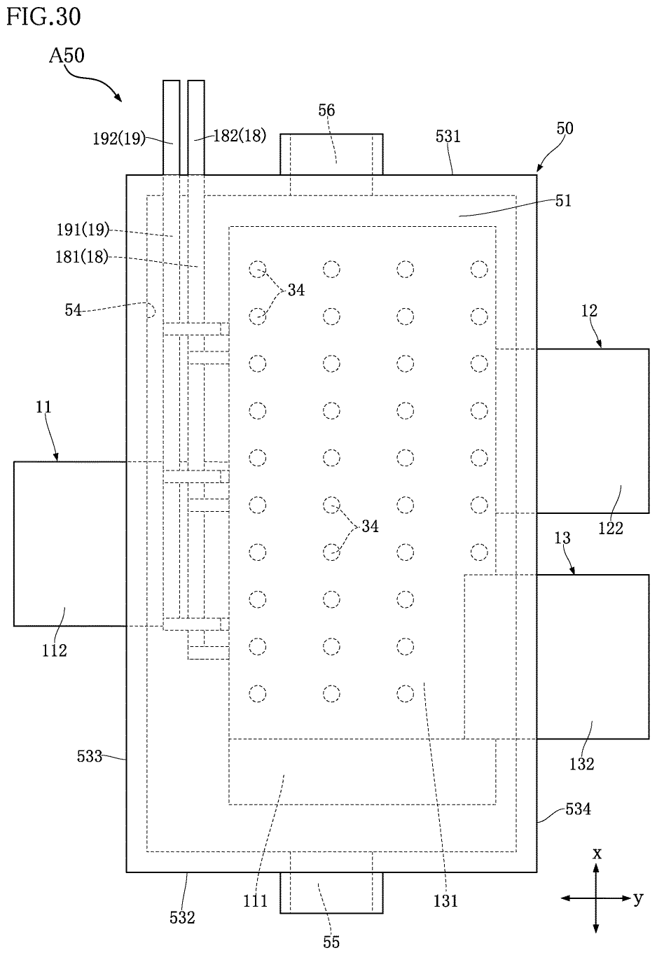

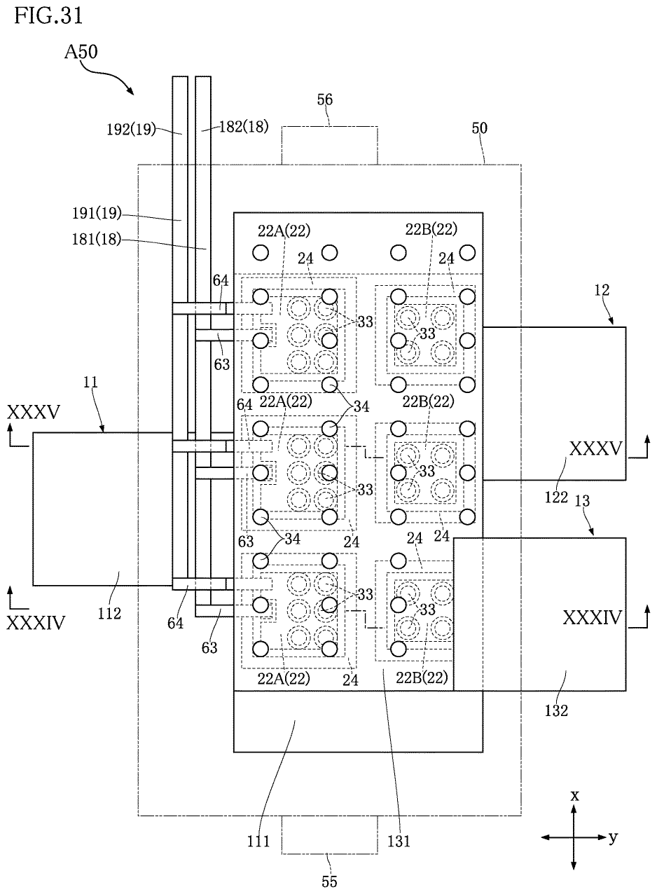

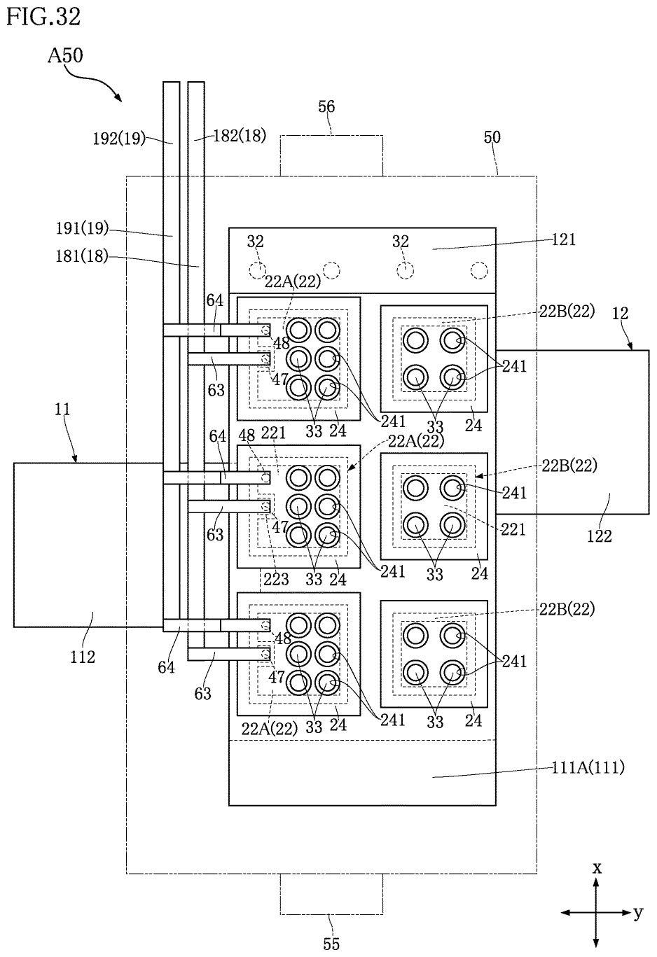

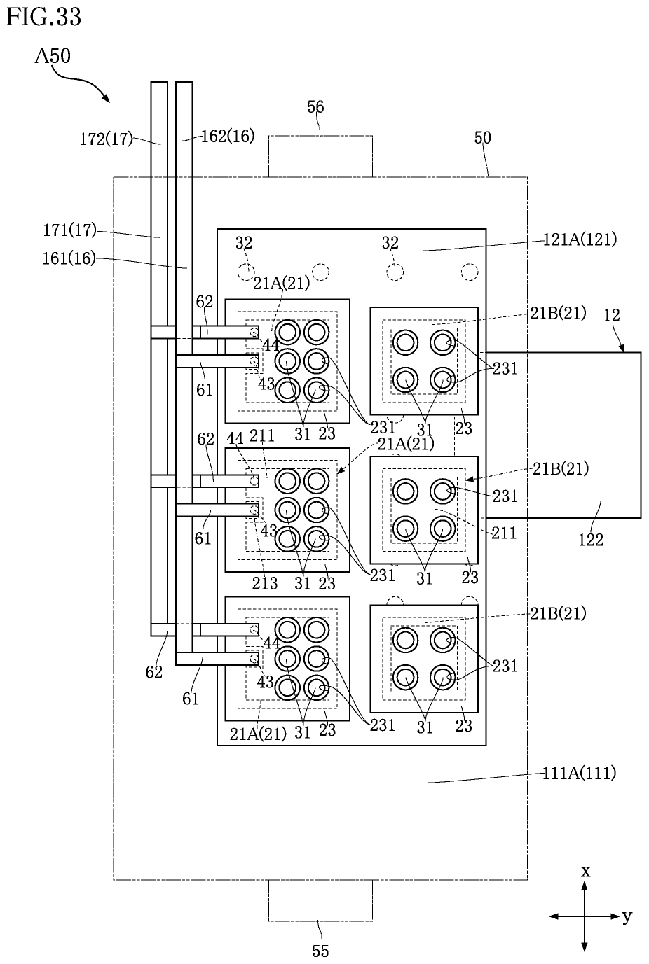

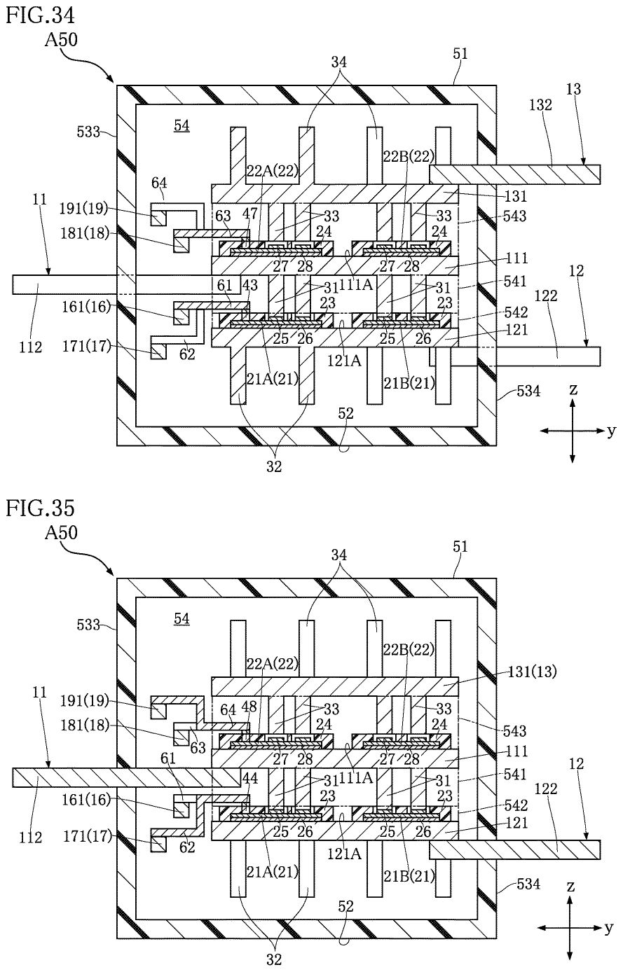

Based on FIGS. 30 to 35, a semiconductor device A50 according to a fifth embodiment of the present disclosure is described. In these figures, the elements identical or similar to those described above for the semiconductor device A10 are designated by the same reference numerals, and redundant descriptions are omitted. Here, FIG. 31 corresponds to FIG. 2 showing the semiconductor device A10. FIG. 32 corresponds to FIG. 3 showing the semiconductor device A10. FIG. 33 corresponds to FIG. 5 showing the semiconductor device A10.

In the semiconductor device A50, the configuration of the first terminal 11, the second terminal 12, the third terminal 13, the first signal terminal 16, the second signal terminal 17, the third signal terminal 18, the fourth signal terminal 19, the housing 50, the plurality of first semiconductor elements 21, and the plurality of second semiconductor elements 22 differ from the corresponding configuration of the semiconductor device A10.

As shown in FIGS. 32 and 35, the first extension portion 112 of the first terminal 11 is located on one side in the third direction y with respect to the first base portion 111. As shown in FIGS. 30 and 35, a portion of the first extension portion 112 protrudes outward from the third side surface 533 of the housing 50.

As shown in FIGS. 31, 33, and 34, the second extension portion 122 of the second terminal 12 and the third extension portion 132 of the third terminal 13 are positioned on a side opposite in the third direction y to the first extension portion 112 of the first terminal 11, with respect to the plurality of first semiconductor elements 21 and the plurality of second semiconductor elements 22. As shown in FIGS. 30, 34, and 35, a portion of each of the second extension portion 122 and the third extension portion 132 protrude outward from the fourth side surface 534 of the housing 50. The second extension portion 122 and the third extension portion 132 are spaced apart from each other in the second direction x.

As shown in FIGS. 30 and 33, the outer portion 162 of the first signal terminal 16 and the outer portion 172 of the second signal terminal 17 protrude outward from the first side surface 531 of the housing 50. As shown in FIG. 30, the outer portion 182 of the third signal terminal 18 and the outer portion 192 of the fourth signal terminal 19 protrude outward from the first side surface 531.

As shown in FIG. 30, the inlet 55 of the housing 50 is opened on the second side surface 532 of the housing 50. The outlet 56 of the housing 50 is opened on the first side surface 531.

As shown in FIGS. 33 to 35, the plurality of first semiconductor elements 21 include a plurality of first switching elements 21A and a plurality of first diodes 21B. The plurality of first diodes 21B are individually connected in parallel with the plurality of first switching elements 21A. Each of the plurality of first switching elements 21A has the first electrode 211, the second electrode 212, and the first gate electrode 213. The plurality of first switching elements 21A are transistors such as MOSFETs or IGBTs. In the semiconductor device A50, the plurality of first switching elements 21A are, for example, MOSFETs. The plurality of first diodes 21B have the first electrode 211, which is the anode, and the second electrode 212, which is the cathode. In the semiconductor device A50, the plurality of first diodes 21B function as reverse-current diodes for the plurality of first switching elements 21A. In the semiconductor device A50, the plurality of first diodes 21B are, for example, Schottky barrier diodes. The first end portion 311 of each of the plurality of first heat dissipation members 31 is conductively bonded to either the first electrode 211 of one of the plurality of first switching elements 21A or the first electrode 211 of one of the plurality of first diodes 21B.

As shown in FIGS. 32, 34, and 35, the plurality of second semiconductor elements 22 include a plurality of second switching elements 22A and a plurality of second diodes 22B. The plurality of second diodes 22B are individually connected in parallel with the plurality of second switching elements 22A. Each of the plurality of second switching elements 22A has the third electrode 221, the fourth electrode 222, and the second gate electrode 223. The plurality of second switching elements 22A are the same elements as the plurality of first switching elements 21A. The plurality of second diodes 22B have the third electrode 221, which is the anode, and the fourth electrode 222, which is the cathode. In the semiconductor device A50, the plurality of second diodes 22B function as reverse-current diodes for the plurality of second switching elements 22A. The plurality of second diodes 22B are the same elements as the plurality of first diodes 21B. The second end portion 331 of each of the plurality of third heat dissipation members 33 is conductively bonded to either the third electrode 221 of one of the plurality of second switching elements 22A or the third electrode 221 of one of the plurality of second diodes 22B.

Therefore, as in the semiconductor device A50, the plurality of first semiconductor elements 21 may be configured not only to include identical elements exclusively but also to include a plurality of types of elements. Similarly, the plurality of second semiconductor elements 22 may be configured not only to include identical elements exclusively but also to include a plurality of types of elements.

Next, the operational effect of the semiconductor device A50 will be described.

The semiconductor device A50 includes the first semiconductor element 21, the first terminal 11, the first heat dissipation member 31, and the first protective layer 23. The first heat dissipation member 31 is electrically connected to the first terminal 11 and is conductively connected to the first electrode 211 of the first semiconductor element 21. In the first direction z, the first flow path 541 is provided between the first semiconductor element 21 and the first terminal 11. The first heat dissipation member 31 is housed within the first flow path 541. Furthermore, at the first opening 231 provided in the first protective layer 23, a gap is provided between the first end portion 311 of the first heat dissipation member 31 inserted into the first opening 231 and the first protective layer 23. Therefore, according to this configuration, it is possible to further improve the cooling efficiency in the semiconductor device A50 as well. Furthermore, the semiconductor device A50 has the configurations common to those of the semiconductor device A10, thereby achieving the operational effects common to those of the semiconductor device A10.

The present disclosure is not limited to the aforementioned embodiments. The specific configurations of each part of the present disclosure are subject to various design modifications.

The present disclosure includes the embodiments described in the following clauses.

### Clause 1

A semiconductor device comprising:
a first semiconductor element having a first electrode positioned on one side in a first direction;
a first terminal opposed the first electrode;
a first heat dissipation member electrically connected to the first terminal and conductively connected to the first electrode; and
a first protective layer covering a portion of the first semiconductor element and being an insulator,
wherein a first flow path is provided between the first semiconductor element and the first terminal in the first direction,
the first heat dissipation member is housed within the first flow path,
a first opening to expose the first electrode is provided in the first protective layer,
the first heat dissipation member has a first end portion inserted into the first opening, and
a gap is provided between the first end portion and the first protective layer at the first opening.

### Claim 2

The semiconductor device according to Clause 1, further comprising a first bonding layer to conductively bond the first electrode and the first end portion.

### Claim 3

The semiconductor device according to Clause 2, wherein the first electrode is in contact with the first flow path.

### Claim 4

The semiconductor device according to Clause 2, wherein a size of a cross-section perpendicular to the first direction of the first opening expands, starting from the first electrode toward the first terminal.

### Clause 5

The semiconductor device according to Clause 4, wherein a size of a cross-section perpendicular to the first direction of the first end portion expands, starting from the first electrode toward the first terminal.

### Clause 6

The semiconductor device according to one of Clauses 1 to 5, further comprising a second terminal positioned on a side opposite from the first terminal with respect to the first semiconductor element,
wherein the first semiconductor element is positioned on a side opposite in the first direction from the first electrode and has a second electrode conductively connected to the second terminal.

### Clause 7

The semiconductor device according to Clause 6, wherein the second electrode is exposed from the first protective layer.

### Clause 8

The semiconductor device according to Clause 7, wherein the first terminal is in contact with the first flow path.

### Clause 9

The semiconductor device according to Clause 8,
wherein a second flow path is provided between the second terminal and the first flow path in the first direction,
the second flow path is connected to the first flow path, and
the second terminal is in contact with the second flow path.

### Clause 10

The semiconductor device according to Clause 9, further comprising a second bonding layer to conductively bond the second terminal and the second electrode.

### Clause 11

The semiconductor device according to Clause 10, wherein the first protective layer is in contact with the second terminal.

### Clause 12

The semiconductor device according to Clause 11, wherein the second bonding layer is in contact with the first protective layer.

### Clause 13

The semiconductor device according to Clause 11, wherein viewed in the first direction, the first protective layer covers an entire periphery of the first semiconductor element.

### Clause 14

The semiconductor device according to Clause 9, further comprising a housing,
wherein the first terminal and the second terminal are supported by the housing, and
the housing has a hollow portion containing the first flow path and the second flow path.

### Clause 15

The semiconductor device according to Clause 14, further comprising a second heat dissipation member connected to the second terminal,
wherein the second heat dissipation member is positioned on a side opposite from the first semiconductor element with respect to the second terminal, and the second heat dissipation member is housed within the hollow portion.

### Clause 16

A method for manufacturing a semiconductor device, comprising:
a first process of conductively bonding a first heat dissipation member to one side of a first terminal in a first direction;
a second process of conductively bonding the first semiconductor element and a second terminal;
a third process of covering a portion of the first semiconductor element and forming a first protective layer, which is an insulator; and
a fourth process of conductively connecting the first heat dissipation member and the first semiconductor element,
wherein the first semiconductor element has a first electrode positioned on a side opposite to a side to face the second terminal in the first direction,
the first heat dissipation member has a first end portion positioned on a side opposite to a side to face the first terminal in the first direction,
in the third process, a first opening to expose the first electrode is formed in the first protective layer,
in the fourth process, the first heat dissipation member is conductively connected to the first electrode by inserting the first end portion into the first opening,
in the fourth process, a first flow path is provided to be positioned between the first semiconductor element and the first terminal in the first direction, and to house the first heat dissipation member, and
in the fourth process, a gap is provided between the first end portion and the first protective layer at the first opening.

### Clause 17

The method for manufacturing a semiconductor device according to Clause 16, wherein i the third process, the formed first protective layer is made to contact the second terminal, a semiconductor device manufacturing method.

### Clause 18

A vehicle comprising:
a drive source; and
the semiconductor device according to Clause 6,
wherein the semiconductor device is conductively connected to the drive source.

### Clause 19

The semiconductor device according to Clause 6, further comprising a first signal terminal,
wherein the first semiconductor element has a first gate electrode positioned on a same side as the first electrode in the first direction, and
the first gate electrode is conductively connected to the first signal terminal.

### Clause 20

The semiconductor device according to Clause 10, further comprising a second semiconductor element positioned on a side opposite side from the first semiconductor element with respect to the first terminal,
wherein the second semiconductor element is conductively connected to the first terminal.

### Clause 21

The semiconductor device according to Clause 20, wherein the second semiconductor element is conductively bonded to the first terminal.

### Clause 22

The semiconductor device according to Clause 21, wherein the second semiconductor element overlaps the first semiconductor element, viewed in the first direction.

### Clause 23

The semiconductor device according to Clause 21 wherein viewed in the first direction, the second semiconductor element is separated from the first semiconductor element.

### Clause 24

The semiconductor device according to Clause 21, further comprising a third terminal positioned on a side opposite side from the first terminal with respect to the second semiconductor element,
wherein the second semiconductor element is conductively connected to the third terminal,
a third flow path is provided between the first terminal and the third terminal in the first direction, and
the second semiconductor element is housed within the third flow path.

### Clause 25

The semiconductor device according to Clause 24, wherein the second terminal and the third terminal are in contact with the third flow path.

### Clause 26

The semiconductor device according to Clause 25, further comprising a third heat dissipation member electrically connected to the third terminal,
wherein the second semiconductor device is conductively connected to the third heat dissipation member, and
the third heat dissipation member is housed within the third flow path

### Clause 27

The semiconductor device according to Clause 26, further comprising a fourth heat dissipation member connected to the third terminal,
wherein the fourth heat dissipation member is positioned on a side opposite from the third heat dissipation member with respect to the third terminal.

### Clause 28.

The semiconductor device according to Clause 13,
wherein the first semiconductor element has a first protective film positioned on a same side as the first electrode in the first direction,
as viewed in the first direction, the first protective film surrounds a periphery of the first electrode, and
the first protective layer covers a portion of the first protective film.

### Clause 29

The semiconductor device according to Clause 14,
wherein the housing has an inlet and an outlet, each communicating with the hollow portion, and
the inlet and the outlet are positioned on sides opposite to each other with respective to the first heat dissipation member in a direction perpendicular to the first direction.

### Clause 30

The semiconductor device according to Clause 29,
wherein the second terminal has a first exposed surface facing a side opposite in the first direction to a side where the first semiconductor element is located, and
the first exposed surface is exposed from the housing.

### REFERENCE NUMERALS

A10 to A50: Semiconductor device B: Vehicle
11: First terminal 111: First base portion
111A: Second mounting surface 112: First extension portion
12: Second terminal 121: Second base portion
121A: Second mounting surface 121B: First exposed surface
122: Second extension portion 13: Third terminal
131: Third base portion 131A: Second exposed surface
132: Third extension portion 16: First signal terminal
161: Inner portion 162: Outer portion
17: Second signal terminal 171: Inner portion
172: Outer portion 18: Third signal terminal
181: Inner portion 182: Outer portion
19: Fourth signal terminal 191: Inner portion
192: Outer portion 21: First semiconductor element
21A: First switching element 21B: First diode
211: First electrode 212: Second electrode
213: First gate electrode 214: First protective Film
22: Second semiconductor element 22A: Second switching element
22B: Second diode 221: Third electrode
222: Fourth electrode 223: Second gate electrode
224: Second protective film 23: First protective layer
231: First opening 24: Second protective layer
241: Second opening 25 to 29: First bonding layer to Fifth bonding layer
31: First heat dissipation member 311: First end portion
32: Second heat dissipation member 33: Third heat dissipation member
331: Second end portion 34: Fourth heat dissipation member
43: First gate Pillar 44: First detection pillar
47: Second gate Pillar 48: Second detection pillar
50: Housing 51: Top surface
52: Bottom surface 531 to 534: First side surface to Fourth side surface
54: Hollow portion 541 to 543: First flow path to Third flow path
55: Inlet 56: Outlet
61-64: First lead to Fourth lead 70: Refrigerant
81: Onboard charger 82: Storage battery
83: Drive system 831: Inverter
832: Drive source P1 to P4: First stage to Fourth process
z: First direction x: Second direction
y: Third direction

1. A semiconductor device comprising:
a first semiconductor element having a first electrode positioned on one side in a first direction;
a first terminal opposed the first electrode;
a first heat dissipation member electrically connected to the first terminal and conductively connected to the first electrode; and
a first protective layer covering a portion of the first semiconductor element and being an insulator,
wherein a first flow path is provided between the first semiconductor element and the first terminal in the first direction,
the first heat dissipation member is housed within the first flow path,
a first opening to expose the first electrode is provided in the first protective layer,
the first heat dissipation member has a first end portion inserted into the first opening, and
a gap is provided between the first end portion and the first protective layer at the first opening.

2. The semiconductor device according to claim 1, further comprising a first bonding layer to conductively bond the first electrode and the first end portion.

3. The semiconductor device according to claim 2, wherein the first electrode is in contact with the first flow path.

4. The semiconductor device according to claim 2, wherein a size of a cross-section perpendicular to the first direction of the first opening expands, starting from the first electrode toward the first terminal.

5. The semiconductor device according to claim 4, wherein a size of a cross-section perpendicular to the first direction of the first end portion expands, starting from the first electrode toward the first terminal.

6. The semiconductor device according to claim 1, further comprising a second terminal positioned on a side opposite from the first terminal with respect to the first semiconductor element,
wherein the first semiconductor element is positioned on a side opposite in the first direction from the first electrode and has a second electrode conductively connected to the second terminal.

7. The semiconductor device according to claim 6, wherein the second electrode is exposed from the first protective layer.

8. The semiconductor device according to claim 7, wherein the first terminal is in contact with the first flow path.

9. The semiconductor device according to claim 8,
wherein a second flow path is provided between the second terminal and the first flow path in the first direction,
the second flow path is connected to the first flow path, and
the second terminal is in contact with the second flow path.

10. The semiconductor device according to claim 9, further comprising a second bonding layer to conductively bond the second terminal and the second electrode.

11. The semiconductor device according to claim 10, wherein the first protective layer is in contact with the second terminal.

12. The semiconductor device according to claim 11, wherein the second bonding layer is in contact with the first protective layer.

13. The semiconductor device according to claim 11, wherein viewed in the first direction, the first protective layer covers an entire periphery of the first semiconductor element.

14. The semiconductor device according to claim 9, further comprising a housing,
wherein the first terminal and the second terminal are supported by the housing, and
the housing has a hollow portion containing the first flow path and the second flow path.

15. The semiconductor device according to claim 14, further comprising a second heat dissipation member connected to the second terminal,
wherein the second heat dissipation member is positioned on a side opposite from the first semiconductor element with respect to the second terminal, and
the second heat dissipation member is housed within the hollow portion.

16. A method for manufacturing a semiconductor device, comprising:
a first process of conductively bonding a first heat dissipation member to one side of a first terminal in a first direction;
a second process of conductively bonding the first semiconductor element and a second terminal;
a third process of covering a portion of the first semiconductor element and forming a first protective layer, which is an insulator; and
a fourth process of conductively connecting the first heat dissipation member and the first semiconductor element,
wherein the first semiconductor element has a first electrode positioned on a side opposite to a side to face the second terminal in the first direction,
the first heat dissipation member has a first end portion positioned on a side opposite to a side to face the first terminal in the first direction,
in the third process, a first opening to expose the first electrode is formed in the first protective layer,
in the fourth process, the first heat dissipation member is conductively connected to the first electrode by inserting the first end portion into the first opening,
in the fourth process, a first flow path is provided to be positioned between the first semiconductor element and the first terminal in the first direction, and to house the first heat dissipation member, and
in the fourth process, a gap is provided between the first end portion and the first protective layer at the first opening.

17. The method for manufacturing a semiconductor device according to claim 16, wherein in the third process, the formed first protective layer is made to contact the second terminal, a semiconductor device manufacturing method.

18. A vehicle comprising:
a drive source; and
the semiconductor device according to claim 6,
wherein the semiconductor device is conductively connected to the drive source.
